(19) United States
(12) Patent Application Publication
(10) Pub. No.: US 2025/0358989 A1
(43) Pub. Date: Nov. 20, 2025

(54) ELECTROMAGNETIC WAVE HEATING DEVICE

(71) Applicant: Mitsubishi Electric Corporation, Tokyo (JP)

(72) Inventors: Hidetoshi MAKIMURA, Tokyo (JP); Yuta SUGIYAMA, Tokyo (JP); Kengo NISHIMOTO, Tokyo (JP)

(73) Assignee: Mitsubishi Electric Corporation, Tokyo (JP)

(21) Appl. No.: 19/284,069

(22) Filed: Jul. 29, 2025

Related U.S. Application Data
(63) Continuation of application No. PCT/JP2023/015394, filed on Apr. 18, 2023.

(51) Int. Cl. H05K 9/00; H05B 6/64; H05B 6/76

(52) U.S. Cl. CPC H05K 9/0056; H05B 6/6414; H05B 6/6426; H05B 6/766; H05K 9/0005; H05K 9/009

(57) ABSTRACT

A conductive housing includes: a first blocking unit that is formed with a first conductive material in a box-like shape having an opening portion; and a second blocking unit including a first electromagnetic wave blocking portion that is formed with a second conductive material and extends in a first direction and a second direction orthogonal to the first direction, and a second electromagnetic wave blocking portion that is formed with a third conductive material, extends in the first direction and the second direction, and is disposed to face the first electromagnetic wave blocking portion at a distance. The second blocking unit is disposed in the opening portion, the first blocking unit is electrically connected to the first electromagnetic wave blocking portion and the second electromagnetic wave blocking portion, and the first blocking unit and the second blocking unit form a space inside.

### CROSS REFERENCE TO RELATED APPLICATION

This application is a Continuation of PCT International Application No. PCT/JP2023/015394, filed on Apr. 18, 2023, which is hereby expressly incorporated by reference into the present application.

### TECHNICAL FIELD

The present disclosure relates to an electromagnetic wave heating device.

### BACKGROUND ART

There has been a disclosed microwave cooking device including a door and a main body (see Patent Literature 1). The microwave cooking device has a microwave shielding panel including a transparent metallic conductive sheet installed in an opening portion of a metallic door. For example, an electromagnetic wave shielding film formed with a transparent metal like the conductive sheet disclosed in Patent Literature 1 is normally created by forming a film of a conductive material such as indium tin oxide (ITO) on a base member.

### CITATION LIST

### Patent Literature

Patent Literature 1: JP 2020-522672 W

### SUMMARY OF INVENTION

### Technical Problem

For example, an electromagnetic wave shielding film formed with a conductive material in an electromagnetic wave heating device is heated by induction of a current by electromagnetic wave, and might be degraded by the heating. When an electromagnetic wave shielding film to be irradiated with electromagnetic wave can secure a sufficient thickness as above, its sheet resistance value is lowered, and thus, heating can be reduced. However, for an electromagnetic wave shielding film formed with a conductive material, it might not be possible to freely set a great thickness due to manufacturing restrictions, and, in such a case, it is difficult to reduce the heating of the electromagnetic wave shielding film, which is a problem.

The present disclosure has been made to solve the problem, and an object is to provide an electromagnetic wave heating device that can reduce heating of electromagnetic wave blocking portions.

### Solution to Problem

An electromagnetic wave heating device according to the present disclosure includes a conductive housing including: a first blocker formed with a first conductive material in a box-like shape having an opening portion; and a second blocker including a first electromagnetic wave blocker that is formed with a second conductive material and extends in a first direction and a second direction orthogonal to the first direction, and a second electromagnetic wave blocker that is formed with a third conductive material, extends in the first direction and the second direction, and is disposed to face the first electromagnetic wave blocker at a distance, and an electromagnetic wave generator to generate electromagnetic wave, the electromagnetic wave generator being disposed in a space formed inside the first blocker and the second blocker; and an electromagnetic wave emitter to emit the electromagnetic wave generated by the electromagnetic wave generator into the space, wherein the second blocker is disposed in the opening portion, and the first blocker is electrically connected to the first electromagnetic wave blocker and the second electromagnetic wave blocker, and a distance between the first electromagnetic wave blocker and the second electromagnetic wave blocker is equal to or within λ×(180°×N±15°)/360°, where λ represents a wavelength of the electromagnetic wave that is generated by the electromagnetic wave generator and propagates between the first electromagnetic wave blocker and the second electromagnetic wave blocker, and N represents an integer equal to or higher than zero.

### Advantageous Effects of Invention

According to the present disclosure, electromagnetic wave is blocked by a blocking unit including a first electromagnetic wave blocking portion and a second electromagnetic wave blocking portion disposed along the first electromagnetic wave blocking portion, so that the sheet resistance value can be lowered even when electromagnetic wave blocking portions not having a sufficient thickness are used, and the heating of the electromagnetic wave blocking portions can be reduced.

### BRIEF DESCRIPTION OF DRAWINGS

FIG. 1 is a perspective view of an electromagnetic wave heating device according to a first embodiment.

FIG. 2 is a schematic cross-sectional view of the electromagnetic wave heating device according to the first embodiment.

FIG. 3 is a cross-sectional view of a second blocking unit according to the first embodiment.

FIG. 4 is a circuit diagram in a case where an electromagnetic wave shielding film according to the first embodiment is illustrated as a two-terminal pair circuit.

FIG. 5A is a graph showing the result of a simulation of power consumption by the second blocking unit according to the first embodiment, and FIG. 5B is a graph showing part of FIG. 5A in an enlarged manner, showing the result of a simulation of power consumption by the second blocking unit according to the first embodiment.

FIG. 6A is a graph showing the result of a simulation of power consumption by a first electromagnetic wave shielding film and a second electromagnetic wave shielding film according to the first embodiment, and FIG. 6B is a graph showing part of FIG. 6A in an enlarged manner, showing the result of a simulation of power consumption by the first electromagnetic wave shielding film and the second electromagnetic wave shielding film according to the first embodiment.

FIGS. 7A and 7B are graphs showing results of calculation of electromagnetic wave blocking efficiency of the second blocking unit according to the first embodiment.

FIG. 8A is a graph showing the result of a simulation of power consumption by a first electromagnetic wave shielding film, a second electromagnetic wave shielding film, and a third electromagnetic wave shielding film according to a modification of the first embodiment, and FIG. 8B is a graph showing part of FIG. 8A in an enlarged manner, showing the result of a simulation of power consumption by the first electromagnetic wave shielding film, the second electromagnetic wave shielding film, and the third electromagnetic wave shielding film according to the modification of the first embodiment.

FIG. 9 is an explanatory diagram schematically showing a sensor device according to the modification of the first embodiment.

FIG. 10 is an enlarged view of a second blocking unit according to a second embodiment as viewed from the normal direction.

FIG. 11A is a graph showing the result of a simulation of power consumption by the second blocking unit according to the second embodiment, and FIG. 11B is a graph showing part of FIG. 11A in an enlarged manner, showing the result of a simulation of power consumption by the second blocking unit according to the second embodiment.

FIG. 12A is a graph showing the result of a simulation of power consumption by a first electromagnetic wave blocking mesh and a second electromagnetic wave blocking mesh according to the second embodiment, and FIG. 12B is a graph showing part of FIG. 12A in an enlarged manner, showing the result of a simulation of power consumption by the first electromagnetic wave blocking mesh and the second electromagnetic wave blocking mesh according to the second embodiment.

FIG. 13 is an enlarged view of a second blocking unit according to a third embodiment as viewed from the normal direction.

FIG. 14 is an enlarged view of the second blocking unit according to the third embodiment, illustrating a state where a first electromagnetic wave blocking mesh and a second electromagnetic wave blocking mesh are arranged to be shifted in a plane direction as viewed from the normal direction.

FIG. 15 is an enlarged view of the second blocking unit according to the third embodiment, illustrating a state where there is an error in the shape of the openings of the second electromagnetic wave blocking mesh, as viewed from the normal direction.

FIG. 16A is a graph showing the result of a simulation of power consumption by the first electromagnetic wave blocking mesh and the second electromagnetic wave blocking mesh according to the third embodiment, and FIG. 16B is a graph showing part of FIG. 16A in an enlarged manner, showing the result of a simulation of power consumption by the first electromagnetic wave blocking mesh and the second electromagnetic wave blocking mesh according to the third embodiment.

FIG. 17 is an enlarged view of a second blocking unit according to a fourth embodiment as viewed from the normal direction.

FIG. 18A is a graph showing the result of a simulation of power consumption by a first electromagnetic wave blocking mesh and a second electromagnetic wave blocking mesh according to the fourth embodiment, and FIG. 18B is a graph showing part of FIG. 18A in an enlarged manner, showing the result of a simulation of power consumption by the first electromagnetic wave blocking mesh and the second electromagnetic wave blocking mesh according to the fourth embodiment.

FIG. 19 is a cross-sectional view of a second blocking unit according to the fifth embodiment.

### DESCRIPTION OF EMBODIMENTS

The following is a detailed description of embodiments according to the present disclosure, with reference to the drawings.

### First Embodiment

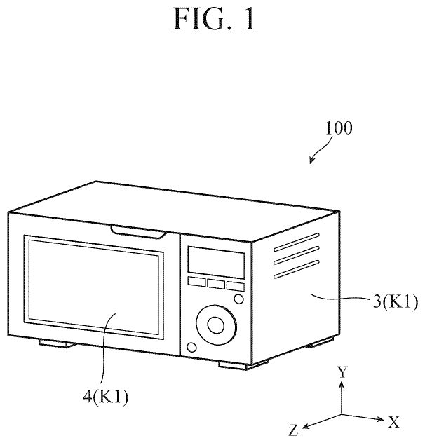

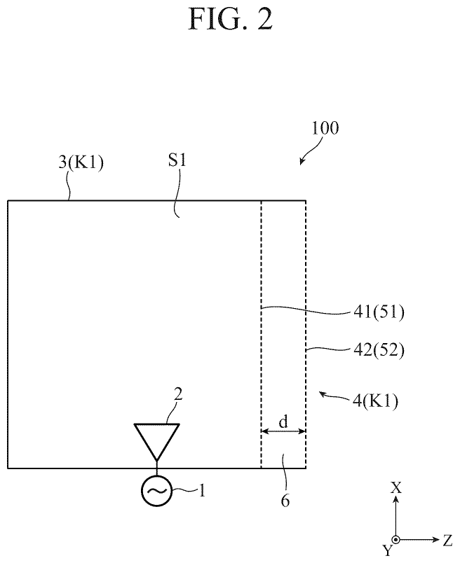

First, a schematic configuration of an electromagnetic wave heating device 100 according to a first embodiment is described with reference to FIGS. 1 to 3. FIG. 1 is a perspective view of a schematic configuration of the electromagnetic wave heating device 100 according to the first embodiment, and FIG. 2 is a cross-sectional diagram schematically showing the electromagnetic wave heating device 100 according to the first embodiment. The electromagnetic wave heating device 100 according to the first embodiment is a microwave oven for cooking, a microwave heating device, or some other electromagnetic wave heating device, and is a device for heating a heating target object by irradiating the target object with electromagnetic wave. As shown in FIGS. 1 and 2, the electromagnetic wave heating device 100 according to the first embodiment includes an electromagnetic wave generating unit 1 that generates electromagnetic wave, an electromagnetic wave emitting unit 2 that emits electromagnetic wave, a housing K1 that houses the electromagnetic wave generating unit 1 and the electromagnetic wave emitting unit 2 therein, and a controller (not shown) that controls the electromagnetic wave generating unit 1.

For example, a magnetron is normally used as the electromagnetic wave generating unit 1. Meanwhile, the electromagnetic wave emitting unit 2 is formed with an antenna that emits the electromagnetic wave generated by the electromagnetic wave generating unit 1, for example. Note that the electromagnetic wave emitting unit may be formed with an opening portion of a waveguide that emits the electromagnetic wave generated by the electromagnetic wave generating unit 1.

The housing K1 as a conductive housing includes a first blocking unit 3 and a second blocking unit 4 that block the electromagnetic wave emitted from the electromagnetic wave emitting unit 2 between the inside and the outside of the housing K1. The housing K1 is designed so that a space S1 is formed therein by the first blocking unit 3 and the second blocking unit 4, and a heating target can be accommodated in the space S1. For example, the housing K1 is formed in a box-like shape with the first blocking unit 3, and the second blocking unit 4 that is disposed so as to close an opening portion formed in part of the first blocking unit 3 to make the inside of the housing K1 visible from the outside, and transmits part of visible light. In other words, the housing K1 includes the first blocking unit 3 formed in a box-like shape having an opening portion, and the second blocking unit disposed in the opening portion. Further, the housing K1 is formed in a rectangular parallelepiped shape, for example, and has a door that can be opened and closed in one of the six surfaces. The first blocking unit 3 is formed with a first conductive material having conductivity, and functions as a conductor shield that blocks the electromagnetic wave emitted from the electromagnetic wave emitting unit 2 into the space S1. For example, the first conductive material forming the first blocking unit 3 is carbon steel, special steel, or some other alloy.

In order for the housing K1 to block the electromagnetic wave emitted from the electromagnetic wave emitting unit 2 between the inside and the outside of the housing K1, it is desirable that the gap communicating the space S inside the housing K1 to the outside of the space S is sufficiently small. For example, the first blocking unit 3 and the second blocking unit 4 communicate the space S to the outside of the space S, and are designed so as not to have a gap larger than 1/10 of the wavelength of the electromagnetic wave emitted from the electromagnetic wave emitting unit 2. Also, in order for the housing K1 to block the electromagnetic wave emitted from the electromagnetic wave emitting unit 2 between the inside and the outside of the housing K1, for example, it is desirable that at least the first blocking unit 3 and the second blocking unit 4 are electrically connected, and the first blocking unit 3 and the second blocking unit 4 form a closed space (the internal space of the housing K1 herein). Note that, in the present disclosure, “being electrically connected” is not necessarily a state in which two components are in contact with each other, and may be a state in which two components are connected to each other by capacitive coupling at an interval narrow enough to sufficiently obtain the ability to block electromagnetic waves. In other words, a first electromagnetic wave blocking portion and a second electromagnetic wave blocking portion may be disposed so that the distance between the first blocking unit 3 and the second blocking unit 4 is short enough to obtain a sufficient ability to block the electromagnetic wave on the entire circumference of each of the portions or at part of the entire circumference at an interval equal to or shorter than 1/10 of the wavelength of the electromagnetic wave to be blocked, and, in this manner, the first blocking unit 3 and the second blocking unit 4 may be electrically connected to each other. Note that, the smaller the size of the gap connecting the inside and the outside of the housing K1, the higher the electromagnetic wave blocking performance. The gap is preferably equal to or shorter than 1/20 of the wavelength of the electromagnetic wave to be blocked.

Alternatively, the first blocking unit 3 and the second blocking unit 4 may be arranged so as to be in contact with each other, and thus, be electrically connected to each other. For example, the second blocking unit 4 may be disposed so as to be in contact with the entire circumference of the rim of the opening of the first blocking unit 3, and thus, be electrically connected to the first blocking unit 3. Alternatively, the first electromagnetic wave blocking portion and the second electromagnetic wave blocking portion may be disposed so as to be in contact with the first blocking unit 3 on the entire circumference of the rim of each of the portions, and thus, be electrically connected to the first blocking unit 3. Note that the first electromagnetic wave blocking portion and the second electromagnetic wave blocking portion may be integrally formed. Further, the first blocking unit 3 and the second blocking unit 4 have reversibility with respect to the direction of the electromagnetic wave to be blocked, and can block any electromagnetic wave emitted from the inside to the outside of the housing K1 and block any electromagnetic wave emitted from the outside to the inside of the housing K1.

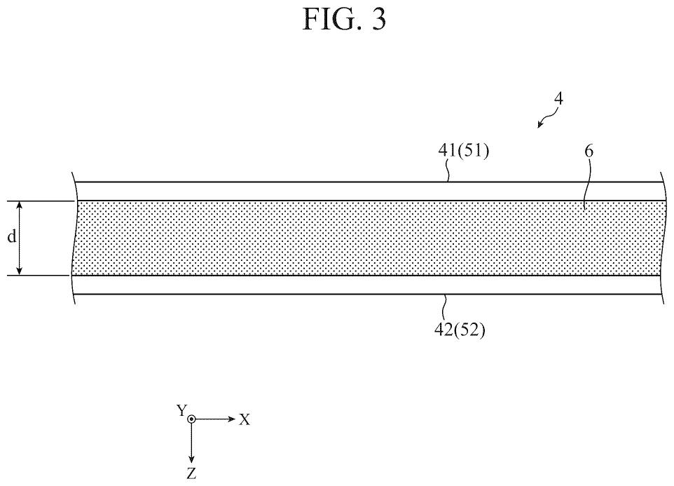

FIG. 3 is a cross-sectional view of the second blocking unit 4 according to the first embodiment. As shown in FIG. 3, the second blocking unit 4 includes a base member 6 held by the first blocking unit 3, a first electromagnetic wave shielding film 41, and a second electromagnetic wave shielding film 42, and shields part of the electromagnetic wave emitted from the electromagnetic wave emitting unit 2 (see FIG. 2). For example, the second blocking unit 4 is disposed at the door of the housing K1. Note that the second blocking unit 4 is only required to form part of the housing K1, and may be disposed at a portion other than the door.

The base member 6 is formed with a non-conductive material, and holds the first electromagnetic wave shielding film 41 and the second electromagnetic wave shielding film 42. The non-conductive material forming the base member 6 is a material having a higher electric resistance than that of the first conductive material forming the first blocking unit 3. For example, the non-conductive material forming the base member 6 is inorganic glass or organic glass such as polyimide, which is a light-transmissive material that transmits part of visible light. Note that the upper temperature limit of the inorganic glass and the heat-resistant polyimide is normally equal to or higher than 200° C., and is suitable for a device that may generate heat when irradiated with a high-power electromagnetic wave, such as the first blocking unit 3 according to the first embodiment. Further, the base member 6 is formed in a plate-like shape, for example, is disposed between the first electromagnetic wave shielding film 41 and the second electromagnetic wave shielding film 42, and holds the first electromagnetic wave shielding film 41 on one surface and holds the second electromagnetic wave shielding film 42 on the other surface. Note that, in the present disclosure, a film is not necessarily a film uniformly formed in a predetermined plane, and may be a film having one or a plurality of openings.

The first electromagnetic wave shielding film 41 as the first electromagnetic wave blocking portion is formed in a film-like shape with a second conductive material, and blocks part of the electromagnetic wave emitted from the electromagnetic wave emitting unit 2. The second electromagnetic wave shielding film 42 as the second electromagnetic wave blocking portion is formed in a film-like shape with a third conductive material, and blocks part of the electromagnetic wave emitted from the electromagnetic wave emitting unit 2. The second conductive material and the third conductive material are materials each having a lower electric resistance than that of the non-conductive material forming the base member 6. Note that the first conductive material, the second conductive material, and the third conductive material may be conductive materials different from one another, or may be the same conductive materials. For example, the second conductive material and the third conductive material are light-transmissive materials that transmit part of visible light, and specifically, are indium tin oxide (ITO).

The second electromagnetic wave shielding film 42 is disposed to face the first electromagnetic wave shielding film 41 at a distance along the first electromagnetic wave shielding film 41. In other words, the first electromagnetic wave shielding film 41 and the second electromagnetic wave shielding film 42 extend in a first direction and a second direction orthogonal to the first direction, and the second electromagnetic wave shielding film 42 is disposed to face the first electromagnetic wave shielding film 41 at a distance in a direction orthogonal to the first electromagnetic wave shielding film 41. Note that, in the description below, the direction orthogonal to the first electromagnetic wave shielding film and the second electromagnetic wave shielding film will be also referred to as the Z direction, a predetermined direction of the directions in which the first electromagnetic wave shielding film and the second electromagnetic wave shielding film extend will be also referred to as the X direction (first direction), and the direction orthogonal to the Z direction and the X direction will be also referred to as the Y direction (second direction) (see FIGS. 1 to 3). Further, the direction that is orthogonal to the X direction and the Y direction, and is opposite to the Z direction will be also referred to as the normal direction.

For example, the second electromagnetic wave shielding film 42 is disposed to face the first electromagnetic wave shielding film 41 at a distance d so as to lie in parallel with the first electromagnetic wave shielding film 41. The second electromagnetic wave shielding film 42 is disposed on the outer side of the housing K1, compared with the first electromagnetic wave shielding film 41. In other words, the second electromagnetic wave shielding film 42 is disposed at a position farther away from the electromagnetic wave emitting unit 2 than the first electromagnetic wave shielding film 41. Therefore, the electromagnetic wave emitted from the electromagnetic wave emitting unit 2 enters the first electromagnetic wave shielding film 41 from the inside, and part of it then exits the second electromagnetic wave shielding film 42 to the outside.

With such a configuration, the electromagnetic wave heating device 100 irradiates the heating target accommodated in the space S1 with electromagnetic wave, converts electric energy into thermal energy via the electromagnetic wave, and thus, heats the heating target. Also, in the electromagnetic wave heating device 100, the housing K1 blocks part of the electromagnetic wave emitted from the electromagnetic wave emitting unit 2.

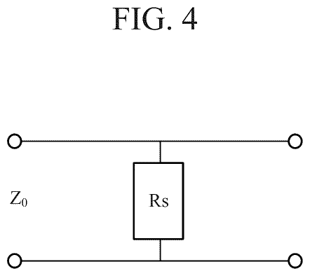

Next, the electric characteristics of the second blocking unit 4 in the electromagnetic wave heating device 100 according to the first embodiment are described with reference to FIGS. 4 to 8. FIG. 4 is a circuit diagram in a case where the first electromagnetic wave shielding film 41 according to the first embodiment is illustrated as a two-terminal pair circuit. In a case where the first electromagnetic wave shielding film 41 is considered to be a virtual circuit as illustrated in FIG. 4, it can be regarded as a two-terminal pair circuit having a sheet resistance value Rs. In a case where the sheet resistance values of the first electromagnetic wave shielding film 41 and the second electromagnetic wave shielding film 42 are the same, and the first electromagnetic wave shielding film 41 and the second electromagnetic wave shielding film 42 are arranged to overlap with each other so as to be in close contact with each other, the total sheet resistance value of the first electromagnetic wave shielding film 41 and the second electromagnetic wave shielding film 42 is Rs/2. In such a case, the sheet resistance value is lower when the second blocking unit includes both the first electromagnetic wave shielding film and the second electromagnetic wave shielding film each having the sheet resistance value Rs than that in a case where the second blocking unit includes only the first electromagnetic wave shielding film having the sheet resistance value Rs.

Normally, when a film formed with a conductive material is irradiated with an electromagnetic wave, the film is heated by induction of a current by the electromagnetic wave. In such a case, the film formed with a conductive material may be deformed or degraded, depending on the magnitude of heating and the number of times heating is performed. Therefore, the electromagnetic wave shielding film of the electromagnetic wave heating device desirably has a sufficiently low sheet resistance value to lower power consumption. As described above, in a case where the first electromagnetic wave shielding film 41 and the second electromagnetic wave shielding film 42 are arranged in an overlapping manner so as to be in close contact with each other, the sheet resistance value is lower when the second blocking unit includes both the first electromagnetic wave shielding film and the second electromagnetic wave shielding film overlapping with each other than that in a case where the second blocking unit includes only the first electromagnetic wave shielding film. Thus, power consumption can be lowered, and heating by electromagnetic wave can be reduced.

However, forming the second electromagnetic wave shielding film 42 on a surface of the first electromagnetic wave shielding film 41 by sputtering or vapor deposition, for example, is synonymous with forming an electromagnetic wave shielding film having a great thickness, and there are cases where it is not possible to freely set the thickness to a great value due to manufacturing restrictions. Moreover, even if the first electromagnetic wave shielding film 41 and the second electromagnetic wave shielding film 42 separately formed are to be brought into close contact with each other, it is difficult to completely bring the first electromagnetic wave shielding film 41 and the second electromagnetic wave shielding film 42 into close contact with each other in an electrical sense, because an adhesive for bonding both shielding films to each other, an oxide film formed on surfaces of both shielding films, a protective film formed during the manufacturing, or a non-conductive substance such as dirt is present between the two shielding films.

Therefore, in the electromagnetic wave heating device 100 according to the first embodiment, the first electromagnetic wave shielding film 41 and the second electromagnetic wave shielding film 42 are arranged so that the electrical distance between the first electromagnetic wave shielding film 41 and the second electromagnetic wave shielding film 42 becomes a specific value, and heating by electromagnetic wave can be reduced.

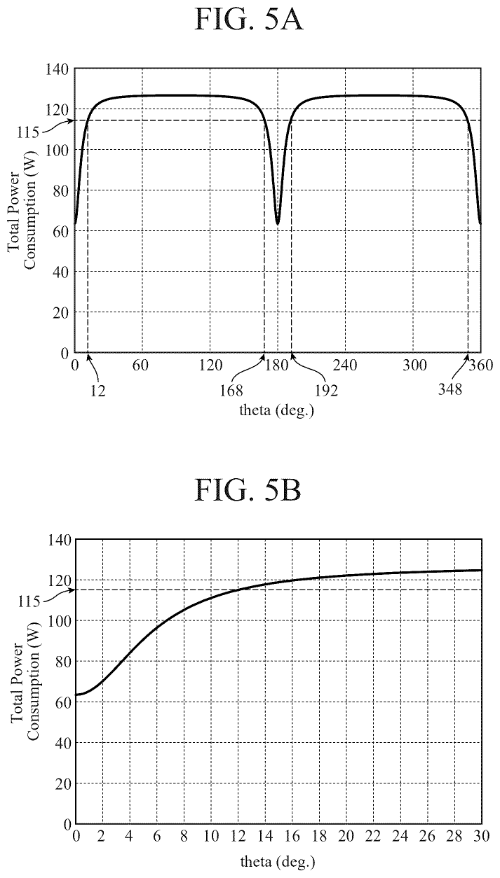

FIG. 5A is a graph showing the result of a simulation of power consumption by the second blocking unit 4 according to the first embodiment, and FIG. 5B is a graph showing part of FIG. 5A in an enlarged manner, showing the result of a simulation of power consumption by the second blocking unit 4 according to the first embodiment. In other words, FIGS. 5A and 5B are graphs showing the total power consumption by the first electromagnetic wave shielding film 41 and the second electromagnetic wave shielding film 42 according to the first embodiment. Specifically, in FIG. 5A, the vertical axis indicates the power consumption [W] by the first electromagnetic wave shielding film 41 and the second electromagnetic wave shielding film 42, and the horizontal axis indicates the electrical distance (electrical length) between the first electromagnetic wave shielding film 41 and the second electromagnetic wave shielding film 42.

In other words, in FIG. 5A, the horizontal axis indicates the length θ (theta) in the angle [deg.] in a case where the length of one wavelength of the electromagnetic wave propagating between the first electromagnetic wave shielding film 41 and the second electromagnetic wave shielding film 42 is 360°, and indicates from 0° to 360°. Also, FIG. 5B shows the portion from 0° to 30° of the graph in FIG. 5A in an enlarged manner. Further, in the simulations according to FIGS. 5A and 5B, the sheet resistance value of each of the first electromagnetic wave shielding film 41 and the second electromagnetic wave shielding film 42 is 20 [Ω/sq.], and the power of the electromagnetic wave entering the first electromagnetic wave shielding film 41 is 663.2 [W]. Note that 20 [Ω/sq.] is a general sheet resistance value of a film formed with IoT. Also, in the simulations according to FIGS. 5A and 5B, the power of the electromagnetic wave entering the first electromagnetic wave shielding film 41 is 663.2 [W]. The value of 663.2 [W] is an example of a value based on a general maximum output of 600 [W] to 1000 [W] for a household microwave oven that is assumed to be required to maintain transparency of the electromagnetic wave blocking portion while reducing the heating of the electromagnetic wave blocking portion. If the area of the electromagnetic wave blocking portion (corresponding to the electromagnetic shield provided in the door portion) in the microwave oven is 25 [cm]×20 [cm]=500 [cm²], and the electromagnetic wave blocking portion is uniformly irradiated with all the electromagnetic wave emitted by the electromagnetic wave emitting unit, the power density of the electromagnetic wave entering the electromagnetic wave blocking portion is 1326.4 [mW/cm²]. The value of the power density is greatly different from electromagnetic waves for communication and broadcasting. For example, in the standard RCR STD-38 related to radio wave protection by Association of Radio Industries and Businesses, an upper limit value of power density in a general environment from 1.5 GHz to 300 GHz is set to 1 mW/cm². As described above, the conductive housing according to the present embodiment is designed for the purpose of blocking electromagnetic wave having a power density of at least 1 mW/cm² or higher.

As shown in FIGS. 5A and 5B, the power consumption by the first electromagnetic wave shielding film 41 and the second electromagnetic wave shielding film 42 is reduced in the vicinities of the electrical distances of 0°, 180°, and 360° between the first electromagnetic wave shielding film 41 and the second electromagnetic wave shielding film 42. Note that it is known that the power consumption in a case where the second electromagnetic wave shielding film 42 is not used and only the first electromagnetic wave shielding film 41 is irradiated with electromagnetic wave under the same conditions is 115.0 [W], and, in the graphs shown in FIGS. 5A and 5B, the power consumption by the first electromagnetic wave shielding film 41 and the second electromagnetic wave shielding film 42 is 115.0 [W] in cases where the electrical distance between the first electromagnetic wave shielding film 41 and the second electromagnetic wave shielding film 42 is 12°, 168°, 192°, and 348°. Accordingly, in a case where the electrical distance between the first electromagnetic wave shielding film 41 and the second electromagnetic wave shielding film 42 is equal to or shorter than 12°, is equal to or within 180°±12°, or is equal to or within 360°+0/−12°, the first electromagnetic wave shielding film 41 and the second electromagnetic wave shielding film 42 can make the power consumption lower than that in a case where electromagnetic wave is blocked by a single electromagnetic wave shielding film having the same sheet resistance value as the first electromagnetic wave shielding film 41.

In other words, where the distance between the first electromagnetic wave shielding film 41 and the second electromagnetic wave shielding film 42 is represented by d, and the wavelength of the electromagnetic wave that is generated by the electromagnetic wave generating unit 1 and propagates between the first electromagnetic wave shielding film 41 and the second electromagnetic wave shielding film 42 is represented by λ, when d is equal to or smaller than λ×12°/360°, is equal to or within λ×(180°±12°)/360°, or is equal to or within λ×(360°+0/−12°)/360°, the second blocking unit 4 can make the power consumption lower than that in a case where electromagnetic wave is blocked by a single electromagnetic wave shielding film having the same sheet resistance value as the first electromagnetic wave shielding film 41.

Note that the power consumption in the first electromagnetic wave shielding film 41 and the second electromagnetic wave shielding film 42 is calculated from the incident power, the transmitted power, and the reflected power with respect to each of the electromagnetic wave shielding films. The incident power on the first electromagnetic wave shielding film 41 is determined by the electromagnetic wave generating unit 1 and the electromagnetic wave emitting unit 2, and the reflected power and the transmitted power of the first electromagnetic wave shielding film 41 and the incident power, the reflected power, and the transmitted power with respect to the second electromagnetic wave shielding film 42 are determined by the incident power on the first electromagnetic wave shielding film 41, the sheet resistance values of the first electromagnetic wave shielding film 41 and the second electromagnetic wave shielding film 42, and the change in phase caused when the electromagnetic wave propagates between the first electromagnetic wave shielding film 41 and the second electromagnetic wave shielding film 42. Because the change to be caused in phase when electromagnetic wave propagates between the first electromagnetic wave shielding film 41 and the second electromagnetic wave shielding film 42 is determined by the propagation distance, it is obvious that, to lower the power consumption in the first electromagnetic wave shielding film 41 and the second electromagnetic wave shielding film 42, d is only required to be equal to or smaller than λ×12°/360°, or be equal to or within λ×(180°×N±12°)/360°, where N represents a positive integer, in addition to the above range. In this manner, it can be seen that the first electromagnetic wave shielding film 41 and the second electromagnetic wave shielding film 42 are not as simple as shielding films preferably having a short electrical distance, and it is possible to reduce the power consumption and the heating in the entire second blocking unit 4 by arranging the shielding films so that the electrical distance between them has a specific value. In other words, the second blocking unit 4 is disposed so that the electrical distance between the first electromagnetic wave shielding film 41 and the second electromagnetic wave shielding film 42 has a value within the above range, and thus, power durability can be enhanced. Note that, as illustrated in FIG. 3, when the first electromagnetic wave shielding film 41 and the second electromagnetic wave shielding film 42 are held on one surface and the other surface of the base member 6, respectively, the distance d between the first electromagnetic wave shielding film 41 and the second electromagnetic wave shielding film 42 depends on the thickness of the base member 6.

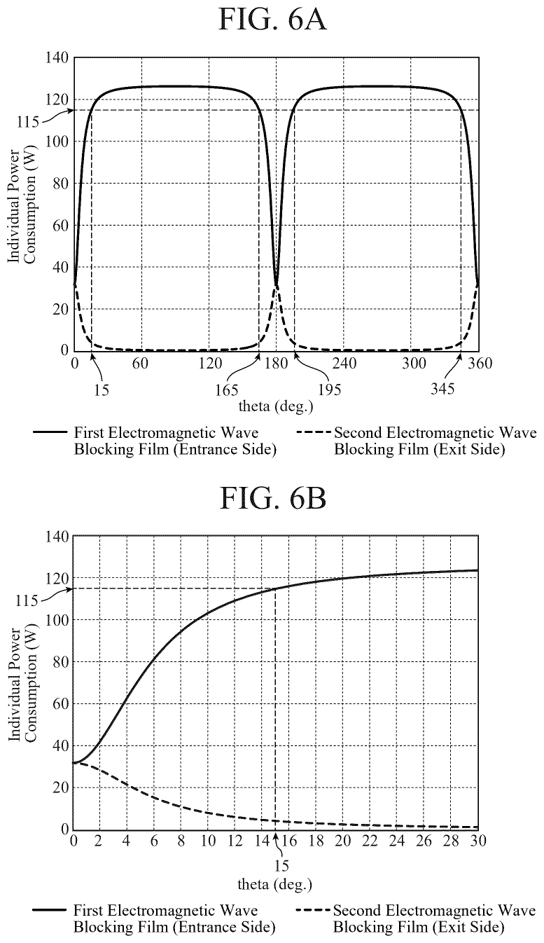

Next, individual power consumption in each of the first electromagnetic wave shielding film 41 and the second electromagnetic wave shielding film 42 is described with reference to FIGS. 6A and 6B. FIG. 6A is a graph showing the result of a simulation of power consumption by the first electromagnetic wave shielding film 41 and the second electromagnetic wave shielding film 42 according to the first embodiment, and FIG. 6B is a graph showing part of FIG. 6A in an enlarged manner, showing the result of a simulation of power consumption by the first electromagnetic wave shielding film 41 and the second electromagnetic wave shielding film 42 according to the first embodiment. Also, FIG. 6B shows the portion from 0° to 30° of the graph in FIG. 6A in an enlarged manner. In FIGS. 6A and 6B, a solid line indicates power consumption by the first electromagnetic wave shielding film 41, and a dashed line indicates power consumption by the second electromagnetic wave shielding film 42. In the simulations according to FIGS. 6A and 6B, conditions such as the sheet resistance value and the power of the electromagnetic wave entering the first electromagnetic wave shielding film are the same as those in the simulations according to FIGS. 5A and 5B. As shown in FIGS. 6A and 6B, the power consumption by the first electromagnetic wave shielding film 41 is reduced in the vicinities of the electrical distances of 0°, 180°, and 360° between the first electromagnetic wave shielding film 41 and the second electromagnetic wave shielding film 42.

As described above, it is known that the power consumption in a case where only the first electromagnetic wave shielding film 41 is irradiated with electromagnetic wave under the same conditions is 115.0 [W], and, in the graphs shown in FIGS. 6A and 6B, the power consumption by the first electromagnetic wave shielding film 41 that consumes more power between the first electromagnetic wave shielding film 41 and the second electromagnetic wave shielding film 42 is 115.0 [W] in cases where the electrical distance between the first electromagnetic wave shielding film 41 and the second electromagnetic wave shielding film 42 is 15°, 165°, 195°, and 345°. Accordingly, in a case where the electrical distance between the first electromagnetic wave shielding film 41 and the second electromagnetic wave shielding film 42 is equal to or shorter than 15°, is equal to or within 180°+15°, or is equal to or within 360°+0/−15°, the power consumption by the first electromagnetic wave shielding film 41 can be made lower than the power consumption by the first electromagnetic wave shielding film 41 in a case where electromagnetic wave is blocked by a single electromagnetic wave shielding film having the same sheet resistance value as the first electromagnetic wave shielding film 41.

In other words, where the distance between the first electromagnetic wave shielding film 41 and the second electromagnetic wave shielding film 42 is represented by d, and the wavelength of the electromagnetic wave that is generated by the electromagnetic wave generating unit 1 and propagates between the first electromagnetic wave shielding film 41 and the second electromagnetic wave shielding film 42 is represented by λ, when d is equal to or smaller than λ×15°/360°, is equal to or within λ×(180°±15°)/360°, or is equal to or within λ×(360°+0/−15°)/360°, the first electromagnetic wave shielding film 41 can make the power consumption lower than that in a case where electromagnetic wave is blocked by a single electromagnetic wave shielding film having the same sheet resistance value as the first electromagnetic wave shielding film 41. Further, where N represents a positive integer, d is only required to be equal to or smaller than λ×15°/360°, or be equal to or within λ×(180°×N±15°)/360° as above.

As described above, the electromagnetic wave heating device 100 according to the first embodiment includes: the electromagnetic wave generating unit 1 that generates electromagnetic wave; the electromagnetic wave emitting unit 2 that emits the electromagnetic wave generated by the electromagnetic wave generating unit 1; and the second blocking unit 4 that includes: the first electromagnetic wave shielding film 41 that is formed with the second conductive material and extends in the X direction and the Y direction; and the second electromagnetic wave shielding film 42 that is formed with the third conductive material, extends in the X direction and the Y direction, and is disposed to face the first electromagnetic wave shielding film 41 at the distance d, and blocks the electromagnetic wave emitted by the electromagnetic wave emitting unit 2. In the electromagnetic wave heating device 100 with this configuration, the first electromagnetic wave shielding film 41 and the second electromagnetic wave shielding film 42 are arranged so that the distance d between the first electromagnetic wave shielding film 41 and the second electromagnetic wave shielding film 42 has a specific value. Thus, the power consumption in the first electromagnetic wave shielding film 41 and the second electromagnetic wave shielding film 42 can be lowered, and heating by electromagnetic wave can be reduced.

In the following, the electromagnetic wave blocking efficiency of the second blocking unit 4 to which the present disclosure is applied is described. Since the second blocking unit 4 is originally a structure provided to block electromagnetic wave, the electromagnetic wave blocking efficiency is an important index of performance of the second blocking unit 4. First, it is known that the electromagnetic wave blocking efficiency SE (dB) in a case where electromagnetic wave enters a conductive film having a sheet resistance value R_{S} [Ω/sq.] in a vacuum having a characteristic impedance Z₀=120×π can be calculated according to the following equation.

SE=−20 log₁₀(2/((Z₀/R_{S})+2))

According to this equation, the electromagnetic wave blocking efficiency SE in a case where only one electromagnetic wave shielding film having a sheet resistance value of 20 [Ω/sq.] is present is 20.4 dB. Further, the electromagnetic wave blocking efficiency SE is 26.0 dB in a case where the thickness of the electromagnetic wave shielding film is doubled, or in a case where the two electromagnetic wave shielding films are overlapped at a distance of 0, which is a case where R_{S} is halved or the sheet resistance value is 10 [Ω/sq.]. Since the sheet resistance value is not limited to this value, and Z₀/R_{S}>>2 is normally satisfied, SE increases by about 6 dB when R_{S} is halved.

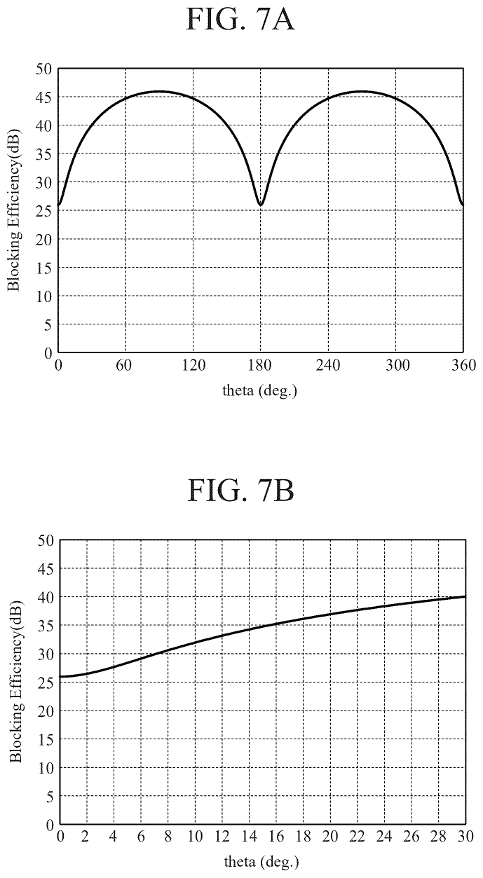

FIGS. 7A and 7B show results of calculation of the electromagnetic wave blocking efficiency SE of the second blocking unit 4 when d, which is the distance between the first electromagnetic wave shielding film 41 and the second electromagnetic wave shielding film 42, is changed. When d=0°, the condition is the same as the condition in a case where a single electromagnetic wave shielding film having a sheet resistance value of 10 [Ω/sq.] exists as described in the previous chapter, and the electromagnetic wave blocking efficiency is 26.0 dB. As is apparent from these graphs, SE is minimized under the condition that d=0°, or d=180°. That is, regardless of to which value d is set, the electromagnetic wave blocking efficiency is superior to that of a single electromagnetic wave shielding film. Furthermore, by setting d under a condition other than d=0° and d=180°, an electromagnetic wave blocking efficiency that is superior to that in a case where the thickness of the electromagnetic wave shielding film is doubled can be obtained. For visible light that naturally passes through an electromagnetic wave shielding film, if the thickness of the electromagnetic wave shielding film is doubled, the transparency is degraded by an equivalent amount, but the amount of degradation does not vary in a case where d=0° and other cases. That is, rather than simply doubling the thickness of an electromagnetic wave shielding film, arranging two electromagnetic wave shielding films at a distance provides an excellent electromagnetic wave blocking efficiency while achieving the same transparency to visible light.

In other words, in the electromagnetic wave heating device according to the first embodiment, the first electromagnetic wave shielding film 41 and the second electromagnetic wave shielding film 42 are arranged so that the distance d between the first electromagnetic wave shielding film 41 and the second electromagnetic wave shielding film 42 has a specific value. Thus, the power consumption in the first electromagnetic wave shielding film 41 and the second electromagnetic wave shielding film 42 can be lowered, and heating by electromagnetic wave can be reduced, while a high electromagnetic wave blocking efficiency is achieved.

Furthermore, the first electromagnetic wave shielding film 41 and the second electromagnetic wave shielding film 42 according to the first embodiment are formed with a light-transmissive material that transmits part of visible light. Because of this, visibility can be ensured when the user visually checks the inside of the housing K1, while the electromagnetic wave emitted toward the user about to visually check the inside of the housing K1 is blocked.

Also, the electromagnetic wave heating device 100 according to the first embodiment includes the base member 6 formed in a plate-like shape with a light-transmissive material transmitting part of visible light, and is designed so that one surface of the base member 6 holds the first electromagnetic wave shielding film 41, and the other surface of the base member 6 holds the second electromagnetic wave shielding film 42. With this arrangement, the second blocking unit 4 can transmit the heat used for heating the first electromagnetic wave shielding film 41 and the second electromagnetic wave shielding film 42 to the base member 6, and moderate the rise in the temperature of the first electromagnetic wave shielding film 41 and the second electromagnetic wave shielding film 42. Further, since the second blocking unit 4 holds the first electromagnetic wave shielding film 41 and the second electromagnetic wave shielding film 42 with one surface and the other surface of a single base member, it is possible to increase the accuracy in the positions of the first electromagnetic wave shielding film 41 and the second electromagnetic wave shielding film 42 in the normal direction and a plane direction orthogonal to the normal direction, to a higher value than that in a case where the first electromagnetic wave shielding film 41 and the second electromagnetic wave shielding film 42 are held by different members. Also, the second blocking unit 4 can reduce the number of components to a smaller number than that in a case where a base member holds the first electromagnetic wave shielding film 41 and the second electromagnetic wave shielding film 42 via another member.

Further, in a case where the base member 6 is formed with inorganic glass, for example, the relative permittivity of general inorganic glass is about 5, and accordingly, the effective wavelength of the electromagnetic wave inside the base member 6 is 1/√(εr) times (about 0.45 times) that in vacuum. Because of this, by having the first electromagnetic wave shielding film 41 and the second electromagnetic wave shielding film 42 held with one surface and the other surface of the base member 6, respectively, it is possible to reduce the physical length between the first electromagnetic wave shielding film 41 and the second electromagnetic wave shielding film 42 to a smaller value in a case where the electrical distance d between the first electromagnetic wave shielding film 41 and the second electromagnetic wave shielding film 42 is set to about 180°×N, than that in a case where the space between the first electromagnetic wave shielding film 41 and the second electromagnetic wave shielding film 42 is vacuum or the like. Thus, the electromagnetic wave heating device can be made smaller in size.

Note that, in the first embodiment, the housing K1 is designed so that the base member 6 formed with a light-transmissive material holds the first electromagnetic wave shielding film 41 and the second electromagnetic wave shielding film 42 formed with a light-transmissive material, but is not limited to this. The housing K1 only needs to be designed to allow visual checking of the inside via the second blocking unit 4. For example, the housing K1 may be designed to allow visual checking of the inside by transmitting part of visible light in at least part of the second blocking unit 4, or may be designed to allow visual checking of the inside by transmitting part of light other than visible light in at least part of the second blocking unit 4.

Alternatively, the second blocking unit may be formed with a non-light-transmissive material, include a first electromagnetic wave blocking portion and a second electromagnetic wave blocking portion each having a plurality of openings, and be designed to allow visual checking of the inside of the housing K1 through the plurality of openings formed in the first electromagnetic wave shielding film and the second electromagnetic wave shielding film, or may be designed to allow visual checking of the inside of the housing K1 through slits formed in the first electromagnetic wave shielding film and the second electromagnetic wave shielding film. For example, the first electromagnetic wave shielding film and the second electromagnetic wave shielding film formed with such a non-light-transmissive material may be formed with carbon steel, special steel, or some other alloy. Furthermore, the first electromagnetic wave shielding film and the second electromagnetic wave shielding film formed with such a non-light-transmissive material do not need to be directly held by a member formed with a light-transmissive material, and may be held by a base member formed with a light-transmissive material via a member formed with some other non-light-transmissive material.

Also, the second blocking unit 4 according to the first embodiment is designed to hold the first electromagnetic wave shielding film 41 and the second electromagnetic wave shielding film 42 with one surface and the other surface of the single base member 6, but is not limited to this. The base member holding the first electromagnetic wave shielding film and the second electromagnetic wave shielding film is not necessarily a single member. For example, the second blocking unit may have a base member formed with a plurality of members formed independently of each other, and the first electromagnetic wave shielding film and the second electromagnetic wave shielding film may be held by different members from each other.

Further, in the first embodiment, the second blocking unit 4 includes the first electromagnetic wave shielding film 41 and the second electromagnetic wave shielding film 42, and is designed to block the electromagnetic wave emitted by the electromagnetic wave emitting unit 2 with the two electromagnetic wave shielding films including the first electromagnetic wave shielding film 41 and the second electromagnetic wave shielding film 42, but is not limited to this. The second blocking unit is only required to have two electromagnetic wave shielding films formed with at least the first electromagnetic wave shielding film 41 and the second electromagnetic wave shielding film 42, and may have equal to or more than three electromagnetic wave shielding films arranged to face one another at a distance, for example.

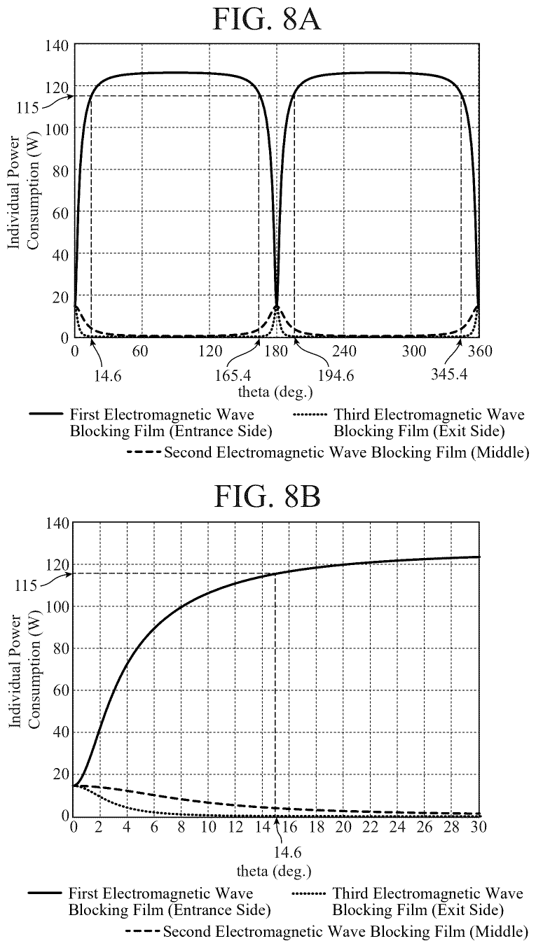

In the following, a modification of the first embodiment is described. FIG. 8A is a graph showing the result of a simulation of power consumption by a first electromagnetic wave shielding film serving as the first electromagnetic wave blocking portion, a second electromagnetic wave shielding film serving as the second electromagnetic wave blocking portion, and a third electromagnetic wave shielding film according to a modification of the first embodiment, and FIG. 8B is a graph showing part of FIG. 8A in an enlarged manner, showing the result of a simulation of power consumption by the first electromagnetic wave shielding film, the second electromagnetic wave shielding film, and the third electromagnetic wave shielding film according to the modification of the first embodiment. Also, FIG. 8B shows the portion from 0° to 30° of the graph in FIG. 8A in an enlarged manner. A second blocking unit according to the modification of the first embodiment differs from the second blocking unit 4 according to the first embodiment in the number of electromagnetic wave shielding films, but the other components are the same, and these configurations same as those of the first embodiment are denoted by the same reference numerals, and explanation thereof is not made herein.

Specifically, the second blocking unit according to the modification of the first embodiment includes the first electromagnetic wave shielding film, the second electromagnetic wave shielding film that is disposed to face the first electromagnetic wave shielding film at a distance in such a manner as to extend along the first electromagnetic wave shielding film, and the third electromagnetic wave shielding film that is disposed to face the second electromagnetic wave shielding film at a distance in such a manner as to extend along the second electromagnetic wave shielding film, at a position opposite to the first electromagnetic wave shielding film, with respect to the second electromagnetic wave shielding film. In other words, the second blocking unit according to the modification of the first embodiment includes the first electromagnetic wave shielding film, the third electromagnetic wave shielding film that is disposed at a distance from the first electromagnetic wave shielding film in such a manner as to extend along the first electromagnetic wave shielding film, and the second electromagnetic wave shielding film that is disposed between the first electromagnetic wave shielding film and the third electromagnetic wave shielding film to face both shielding films at a distance from each of the first electromagnetic wave shielding film and the third electromagnetic wave shielding film in such a manner as to extend along the first electromagnetic wave shielding film. As the second blocking unit according to the modification of the first embodiment disperses the power consumption by the three electromagnetic wave shielding films formed with the first electromagnetic wave shielding film, the second electromagnetic wave shielding film, and the third electromagnetic wave shielding film in this manner, the power consumption and the heating per film is further reduced to smaller amounts than those in the case where two electromagnetic wave shielding films are used.

In FIGS. 8A and 8B, a solid line indicates power consumption by the first electromagnetic wave shielding film, a dashed line indicates power consumption by the second electromagnetic wave shielding film, and a dotted line indicates power consumption by the third electromagnetic wave shielding film. In the simulations according to FIGS. 8A and 8B, the distance between the first electromagnetic wave shielding film and the second electromagnetic wave shielding film is the same as the distance between the second electromagnetic wave shielding film and the third electromagnetic wave shielding film, the wavelength of the electromagnetic wave between the first electromagnetic wave shielding film and the second electromagnetic wave shielding film is the same as the wavelength of the electromagnetic wave between the second electromagnetic wave shielding film and the third electromagnetic wave shielding film, the sheet resistance value of each of the first electromagnetic wave shielding film, the second electromagnetic wave shielding film, and the third electromagnetic wave shielding film is 20 [Ω/sq.], and the power of the electromagnetic wave entering the first electromagnetic wave shielding film is 663.2 [W]. As shown in FIGS. 8A and 8B, the power consumption by the first electromagnetic wave shielding film is reduced in the vicinities of the electrical distances of 0°, 180°, and 360° among the first electromagnetic wave shielding film, the second electromagnetic wave shielding film, and the third electromagnetic wave shielding film.

Furthermore, it is known that the power consumption in a case where only the first electromagnetic wave shielding film is irradiated with electromagnetic wave under the same conditions is 115.0 [W] as described above, and, in the graphs shown in FIGS. 8A and 8B, the power consumption by the first electromagnetic wave shielding film that consumes the largest amount of power among the first electromagnetic wave shielding film, the second electromagnetic wave shielding film, and the third electromagnetic wave shielding film is 115.0 [W] in cases where the electrical distance between the first electromagnetic wave shielding film and the second electromagnetic wave shielding film is 14.6°, 165.4°, 194.6°, and 345.4°. Accordingly, in a case where the electrical distance among the first electromagnetic wave shielding film, the second electromagnetic wave shielding film, and the third electromagnetic wave shielding film is equal to or shorter than 14.6°, is equal to or within 180°±14.6°, or is equal to or within 360°+0/−14.6°, the power consumption by the first electromagnetic wave shielding film can be made lower than the power consumption by the first electromagnetic wave shielding film in a case where electromagnetic wave is blocked by a single electromagnetic wave shielding film having the same sheet resistance value as the first electromagnetic wave shielding film.

In other words, where the distance among the first electromagnetic wave shielding film, the second electromagnetic wave shielding film, and the third electromagnetic wave shielding film is represented by d, and the wavelength of the electromagnetic wave that is generated by the electromagnetic wave generating unit 1 and propagates between the first electromagnetic wave shielding film and the second electromagnetic wave shielding film, and between the second electromagnetic wave shielding film and the third electromagnetic wave shielding film is represented by λ, when d is equal to or smaller than λ×14.6°/360°, is equal to or within λ×(180°±14.6°)/360°, or is equal to or within λ×(360°+0/−14.6°)/360°, the first electromagnetic wave shielding film can make the power consumption lower than that in a case where electromagnetic wave is blocked by a single electromagnetic wave shielding film having the same sheet resistance value as the first electromagnetic wave shielding film. Further, where N represents a positive integer, d is only required to be equal to or smaller than λ×14.6°/360°, or be equal to or within λ×(180°×N±14.6°)/360° as above.

Note that, in FIGS. 8A and 8B, when each electrical distance among the first electromagnetic wave shielding film, the second electromagnetic wave shielding film, and the third electromagnetic wave shielding film is equal to or shorter than 2°, is equal to or within 180°±2°, or is in the range of 360°+0/−2°, the power consumption in the first electromagnetic wave shielding film is much lower than those in the cases shown in FIGS. 6A and 6B, and the effect is particularly high.

Although an electromagnetic wave heating device that is typically a microwave oven has been described as an example of the first embodiment, the points of the present disclosure lie in the facts that an electromagnetic wave blocking window capable of reducing heat generation and the degradation to be caused by the heat generation even when a high-power electromagnetic wave enters is achieved, and a metal housing that has an opening portion and is capable of maintaining electromagnetic wave blocking efficiency is obtained, and therefore, applications are not limited to electromagnetic wave heating devices. As another mode of the first embodiment, a case where the embodiment is applied to a protection means against an attack technique (high power microwave attack: HPM attack) by which a high-power electromagnetic wave is emitted to damage and destroy an electronic device is described herein.

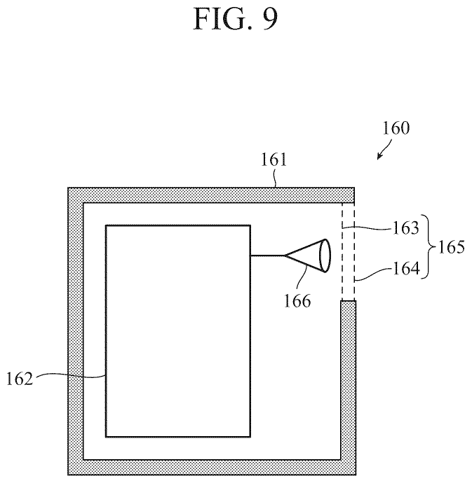

FIG. 9 is an explanatory diagram of a sensor device 160 to which the present disclosure is applied, in which a closed space is formed by electrical connection between a first blocking unit 161 and a second blocking unit 165 that is formed with a first electromagnetic wave shielding film 163 and a second electromagnetic wave shielding film 164, and electromagnetic wave is blocked inside and outside the closed space. In the closed space, a sensor processing device 162 and a sensor element 166 connected to the sensor processing device are provided, and the sensor element 166 senses the outside of the closed space via the second blocking unit. In other words, the sensor element 166 acquires information from the outside of the closed space via the second blocking unit. For example, the sensor element 166 acquires visual information from the outside of the closed space via the second blocking unit. The information acquired by the sensor element 166 is processed by the sensor processing device 162, and is stored into a storage device (not shown) or is transmitted to another device (not shown) in a wired or wireless manner. For example, the sensor element 166 is an element that captures an image of the outside of the closed space using visible light or infrared light, and is typically a visible-light or infrared camera. Alternatively, the sensor device 160 may be a sensor device attached to a vehicle that may be manned or unmanned, a flying object including an aircraft, a vessel, or the like and further, the first blocking unit 161 may partially or entirely share a conductive structure such as a vehicle, a flying object including or an aircraft, a vessel, or the like.

In a case where the sensor device 160 does not include the first blocking unit 161 and the second blocking unit 165, when a high-power electromagnetic wave enters, a large current is induced in the sensor element 166 and the cable or the like connecting the sensor element 166 to the sensor processing device 162, which breaks semiconductor components and electronic circuits constituting the sensor element 166 and the sensor processing device 162. Therefore, it is necessary to electrically shield the entire sensor device, but, when the entire sensor device is covered with a metallic housing, visible light and infrared light are also blocked, and therefore, the sensor element 166 cannot serve the original purpose of capturing images of the surroundings. Further, with a normal metallic mesh or punching metal shield, the field of view of the sensor element 166 is obstructed, and sensing results will be impaired. Therefore, an opening portion is formed in the first blocking unit 161, and the second blocking unit 165 that transmits visible light or infrared light and can block electromagnetic wave (so-called radio waves having a longer wavelength than infrared rays) is disposed in the opening portion, so that destruction of the sensor processing device 162 and the sensor element 166 can be prevented by the blocking units served as the blocking structure against a high-power electromagnetic wave entering from the outside. Meanwhile, light having a shorter wavelength than that of infrared light is transmitted through the second blocking unit, and thus, the sensor element 166 can serve the original purpose of capturing an image of the surroundings. Note that the sensor device 160 includes the sensor element 166 and the sensor processing device 162 disposed in the space formed by the first blocking unit 161 and the second blocking unit 165, but is not limited to this. The sensor device is only required to include at least a sensor element disposed in the space, and may include a sensor element disposed in the space, and a sensor processing device that is communicably connected to the sensor element and is disposed outside the space, for example.

For this purpose, the second blocking unit 165 is required to be transparent to light having a wavelength shorter than that of infrared light, to achieve a high electromagnetic wave blocking efficiency, and not to degrade the characteristics even when a high-power electromagnetic wave enters. Therefore, the requirements are the same as those for the second blocking unit 4 of the electromagnetic wave heating device described above. In view of this, the application of the present disclosure described using the above-described electromagnetic wave heating device as an example is appropriate. By adopting the present disclosure, it is possible to achieve an excellent electromagnetic wave blocking efficiency while reducing power consumption in the second blocking unit and avoiding heating of the electromagnetic wave blocking portions and characteristics degradation caused by the heating even when a high-power electromagnetic wave enters the sensor device 160.

### Second Embodiment

Next, an electromagnetic wave heating device according to a second embodiment is described with reference to FIG. 1 and FIGS. 10 to 12. The electromagnetic wave heating device according to the second embodiment differs from the electromagnetic wave heating device 100 according to the first embodiment in the shape of the first electromagnetic wave blocking portion and the second electromagnetic wave blocking portion, but the other components are the same, and the same components as those of the first embodiment are denoted by the same reference signs as those used in the first embodiment and are not explained herein.

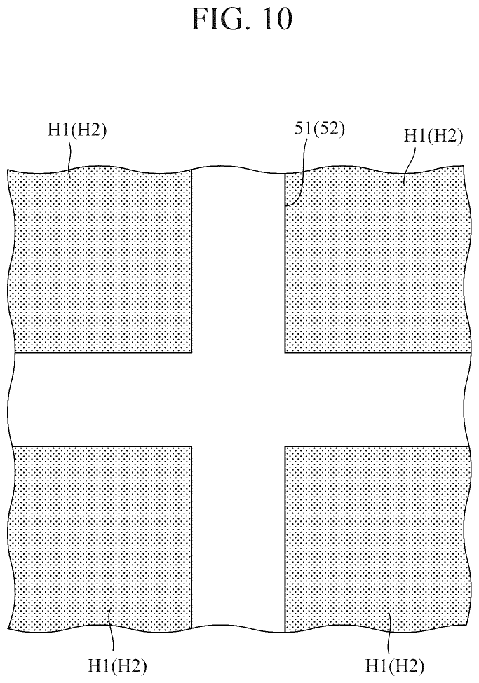

FIG. 10 is an enlarged view of a second blocking unit according to the second embodiment as viewed from the normal direction. In other words, FIG. 10 is an enlarged view of the second blocking unit according to the second embodiment as viewed from the positive side in the Z direction toward the negative side in the Z direction. As illustrated in FIGS. 1 and 10, the second blocking unit according to the second embodiment includes a first electromagnetic wave blocking mesh 51 as a first electromagnetic wave blocking portion that has a plurality of openings H1 and is formed in a net-like shape extending in the X direction and the Y direction, and a second electromagnetic wave blocking mesh 52 as a second electromagnetic wave blocking portion that has a plurality of openings H2, is formed in a net-like shape extending in the X direction and the Y direction, and is disposed at a distance from the first electromagnetic wave blocking mesh 51 in a direction opposite to the Z direction. Also, the first electromagnetic wave blocking mesh 51 and the second electromagnetic wave blocking mesh 52 are arranged so that the edge lines (the outlines) of the openings H1 and the edge lines of the openings H2 overlap when viewed from the normal direction. Note that, in FIG. 10, hatched portions indicate the openings H1 and the openings H2.

In other words, the first electromagnetic wave blocking mesh 51 is formed in a net-like shape having the plurality of openings H1 including first openings and second openings, the second electromagnetic wave blocking mesh 52 is formed in a net-like shape having the plurality of openings H2 including third openings and fourth openings, the third openings are formed so as to overlap the first openings when viewed from the normal direction orthogonal to the second electromagnetic wave blocking mesh 52, and the edge lines of the third openings are arranged so as not to intersect the edge lines of the first openings when viewed from the normal direction. Further, the second openings are formed so as to be adjacent to the first openings, the fourth openings are formed so as to be adjacent to the third openings, and are formed so as to overlap the second openings when viewed from the normal direction, and the edge lines of the fourth openings are positioned so as not to intersect the edge lines of the second openings when viewed from the normal direction.

For example, the second blocking unit according to the second embodiment includes the first electromagnetic wave blocking mesh 51 formed in a net-like (mesh-like) shape having a plurality of fine openings H1 each having a polygonal shape such as a triangle, a rhombus, a parallelogram, a rectangle, a square, or a hexagon, a circle, an ellipse, or some other shape, and the second electromagnetic wave blocking mesh 52 formed in a net-like shape having a plurality of openings H2 having the same shape, the same size, and the same interval as those of the openings H1, and the openings H1 of the first electromagnetic wave blocking mesh 51 and the openings H2 of the second electromagnetic wave blocking mesh 52 are formed so that the edge lines thereof overlap. Further, the first electromagnetic wave blocking mesh 51 and the second electromagnetic wave blocking mesh 52 are metal meshes formed by etching or the like, and are formed with a conductive material that is a non-light-transmissive material. The second blocking unit according to the second embodiment is designed so that the inside thereof can be visually seen from the outside the housing K1 through the openings H1 and H2.

For example, in a case where a first electromagnetic wave shielding film and a second electromagnetic wave shielding film having no openings are formed with a light-transmissive material over the entire surface of the base member 6, the user observes the inside through both the first electromagnetic wave shielding film and the second electromagnetic wave shielding film stacked in the normal direction, and therefore, the visibility is lower than that in a case where a single electromagnetic wave shielding film is used. On the other hand, in the second blocking unit according to the second embodiment, the first electromagnetic wave blocking mesh 51 and the second electromagnetic wave blocking mesh 52 have the openings H1 and H2, so that the decrease in visibility due to the overlapping of the first electromagnetic wave blocking mesh 51 and the second electromagnetic wave blocking mesh 52 in the normal direction is reduced, and the visibility of the inside of the housing K1 can be increased.

Furthermore, as the first electromagnetic wave blocking mesh 51 and the second electromagnetic wave blocking mesh 52 have a plurality of openings, the sheet resistance value is higher than that of electromagnetic wave shielding films having no openings, but the degrees of freedom in material and thickness are high, because the electromagnetic wave shielding films do not need to be formed with a light-transmissive material. Further, in a case where the first electromagnetic wave blocking mesh 51 and the second electromagnetic wave blocking mesh 52 are formed with a light-transmissive material, for example, it is possible to make the visibility of the inside of the housing K1 even higher than that in a case with electromagnetic wave shielding films having no openings.

Note that the first electromagnetic wave blocking mesh and the second electromagnetic wave blocking mesh are not limited to those having a plurality of openings arranged at the same intervals, but may be formed so that the distance between the openings varies depending on the position in a plane direction orthogonal to the normal direction, or may have openings arranged at random intervals or formed in various shapes. For example, the first blocking unit, and the first electromagnetic wave blocking mesh 51 and the second electromagnetic wave blocking mesh 52 are electrically connected to each other as described in the first embodiment, but, to make the connection more surely, solid electrodes, instead of mesh electrodes, may be formed on the outer peripheral portions of the first electromagnetic wave blocking mesh 51 and the second electromagnetic wave blocking mesh 52. As it is possible to surely make the electrical connection by connecting the first blocking unit 3 and the second blocking unit 4 via a conductive member having a wider area in this manner, the electrical connection can be more reliably made. Thus, the electromagnetic wave blocking efficiency is improved, the heat dissipation from the second blocking unit 4 to the first blocking unit 3 is also improved, and the heating of the second blocking unit 4 by electromagnetic wave can be reduced.

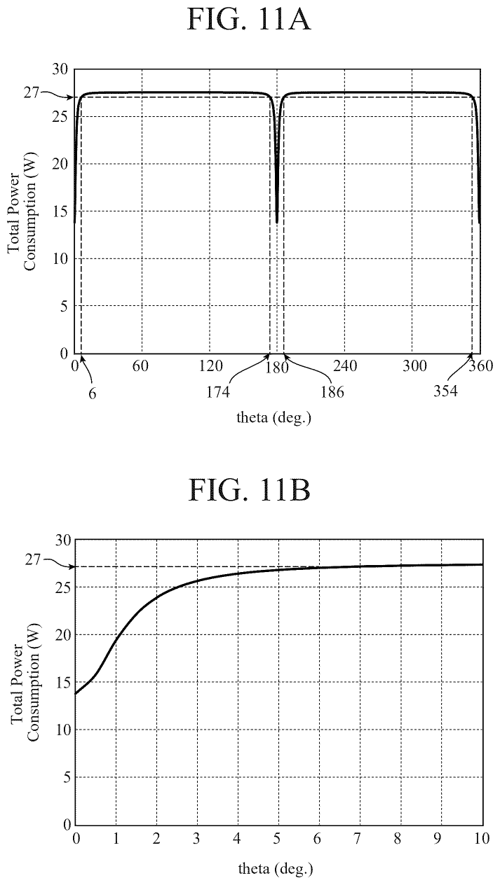

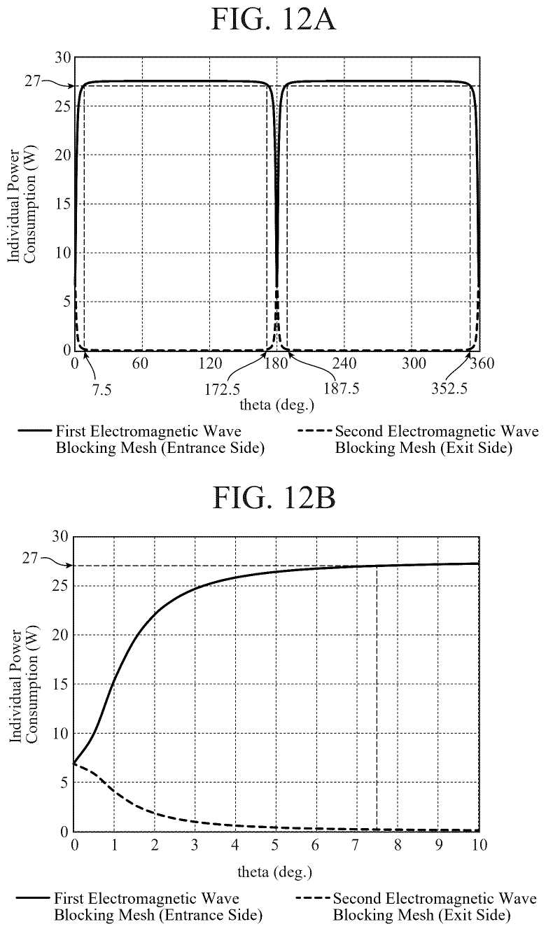

Next, the electric characteristics of the second blocking unit in the electromagnetic wave heating device 100 according to the second embodiment are described with reference to FIGS. 11 and 12. FIG. 11A is a graph showing the result of a simulation of power consumption by the second blocking unit according to the second embodiment, and FIG. 11B is a graph showing part of FIG. 11A in an enlarged manner, showing the result of a simulation of power consumption by the second blocking unit according to the second embodiment.

In other words, FIGS. 11A and 11B are graphs showing the total power consumption by the first electromagnetic wave blocking mesh 51 and the second electromagnetic wave blocking mesh 52 according to the second embodiment. Also, FIG. 11B shows the portion from 0° to 10° of the graph in FIG. 11A in an enlarged manner. In the simulations according to FIGS. 11A and 11B, the sheet resistance value of each of the first electromagnetic wave blocking mesh 51 and the second electromagnetic wave blocking mesh 52 is 4 [Ω/sq.], and the power of the electromagnetic wave entering the first electromagnetic wave blocking mesh 51 is 663.2 [W]. Note that 4 [Ω/sq.] is a general sheet resistance value of a metal mesh formed with a light-transmissive material.

As shown in FIGS. 11A and 11B, the power consumption by the first electromagnetic wave blocking mesh 51 and the second electromagnetic wave blocking mesh 52 is reduced in the vicinities of the electrical distances of 0°, 180°, and 360° between the first electromagnetic wave blocking mesh 51 and the second electromagnetic wave blocking mesh 52. Note that it is known that the power consumption in a case where the second electromagnetic wave blocking mesh 52 is not used and only the first electromagnetic wave blocking mesh 51 is irradiated with electromagnetic wave under the same conditions is 27.0 [W], and, in the graphs shown in FIGS. 11A and 11B, the power consumption by the first electromagnetic wave blocking mesh 51 and the second electromagnetic wave blocking mesh 52 is 27.0 [W] in cases where the electrical distance between the first electromagnetic wave blocking mesh 51 and the second electromagnetic wave blocking mesh 52 is 6°, 174°, 186°, and 354°.

Accordingly, in a case where the electrical distance between the first electromagnetic wave blocking mesh 51 and the second electromagnetic wave blocking mesh 52 is equal to or shorter than 6°, is equal to or within 180°±6°, or is equal to or within 360°+0/−6°, the first electromagnetic wave blocking mesh 51 and the second electromagnetic wave blocking mesh 52 can make the power consumption lower than that in a case where electromagnetic wave is blocked by a single electromagnetic wave blocking mesh having the same sheet resistance value as the first electromagnetic wave blocking mesh 51. In other words, where the distance between the first electromagnetic wave blocking mesh 51 and the second electromagnetic wave blocking mesh 52 is represented by d, and the wavelength of the electromagnetic wave that is generated by the electromagnetic wave generating unit 1 and propagates between the first electromagnetic wave blocking mesh 51 and the second electromagnetic wave blocking mesh 52 is represented by λ, when d is equal to or smaller than λ×6°/360°, is equal to or within λ×(180°±6°)/360°, or is equal to or within λ×(360°+0/−6°)/360°, the first electromagnetic wave blocking mesh 51 can make the power consumption lower than that in a case where electromagnetic wave is blocked by a single electromagnetic wave blocking mesh having the same sheet resistance value as the first electromagnetic wave blocking mesh 51. Further, where N represents a positive integer, d is only required to be equal to or smaller than λ×6°/360°, or be equal to or within λ×(180°×N±6°)/360° as above.

FIG. 12A is a graph showing the result of a simulation of power consumption by the first electromagnetic wave blocking mesh 51 and the second electromagnetic wave blocking mesh 52 according to the second embodiment, and FIG. 12B is a graph showing part of FIG. 12A in an enlarged manner, showing the result of a simulation of power consumption by the first electromagnetic wave blocking mesh 51 and the second electromagnetic wave blocking mesh 52 according to the second embodiment. Also, FIG. 12B shows the portion from 0° to 10° of the graph in FIG. 12A in an enlarged manner.

In FIGS. 12A and 12B, a solid line indicates power consumption by the first electromagnetic wave blocking mesh 51, and a dashed line indicates power consumption by the second electromagnetic wave blocking mesh 52. In the simulations according to FIGS. 12A and 12B, conditions such as the sheet resistance value and the power of the electromagnetic wave entering the first electromagnetic wave blocking mesh 51 are the same as those in the simulations according to FIGS. 11A and 11B. As shown in FIGS. 12A and 12B, the power consumption by the first electromagnetic wave blocking mesh 51 is reduced in the vicinities of the electrical distances of 0°, 180°, and 360° between the first electromagnetic wave blocking mesh 51 and the second electromagnetic wave blocking mesh 52.

As described above, it is known that the power consumption in a case where only the first electromagnetic wave blocking mesh 51 is irradiated with electromagnetic wave under the same conditions is 27.0 [W], and, in the graphs of the first electromagnetic wave blocking mesh 51 and the second electromagnetic wave blocking mesh 52 shown in FIGS. 12A and 12B, the power consumption by the first electromagnetic wave blocking mesh 51 that consumes more power is 27.0 [W] in cases where the electrical distance between the first electromagnetic wave blocking mesh 51 and the second electromagnetic wave blocking mesh 52 is 7.5°, 172.5°, 187.5°, and 352.5°. Accordingly, in a case where the electrical distance between the first electromagnetic wave blocking mesh 51 and the second electromagnetic wave blocking mesh 52 is equal to or shorter than 7.5°, is equal to or within 180°+7.5°, or is equal to or within 360°+0/−7.5°, the power consumption by the first electromagnetic wave blocking mesh 51 can be made lower than the power consumption by the first electromagnetic wave blocking mesh 51 in a case where electromagnetic wave is blocked by a single electromagnetic wave blocking mesh having the same sheet resistance value as the first electromagnetic wave blocking mesh 51.

In other words, where the distance between the first electromagnetic wave blocking mesh 51 and the second electromagnetic wave blocking mesh 52 is represented by d, and the wavelength of the electromagnetic wave that is generated by the electromagnetic wave generating unit 1 and propagates between the first electromagnetic wave blocking mesh 51 and the second electromagnetic wave blocking mesh 52 is represented by λ, when d is equal to or smaller than 2×7.5°/360°, is equal to or within λ×(180°+7.5°)/360°, or is equal to or within λ×(360°+0/−7.5°)/360°, the first electromagnetic wave blocking mesh 51 can make the power consumption lower than that in a case where electromagnetic wave is blocked by a single electromagnetic wave blocking mesh having the same sheet resistance value as the first electromagnetic wave blocking mesh 51. Further, where N represents a positive integer, d is only required to be equal to or smaller than λ×7.5°/360°, or be equal to or within λ×(180°×N±7.5°)/360° as above.

### Third Embodiment

Next, an electromagnetic wave heating device according to a third embodiment is described with reference to FIG. 1 and FIGS. 13 to 16. The electromagnetic wave heating device according to the third embodiment differs from the electromagnetic wave heating device according to the second embodiment in the shape of the openings of the second electromagnetic wave blocking portion, but the other components are the same, and the same components as those of the second embodiment are denoted by the same reference signs as those used in the second embodiment and are not explained herein.

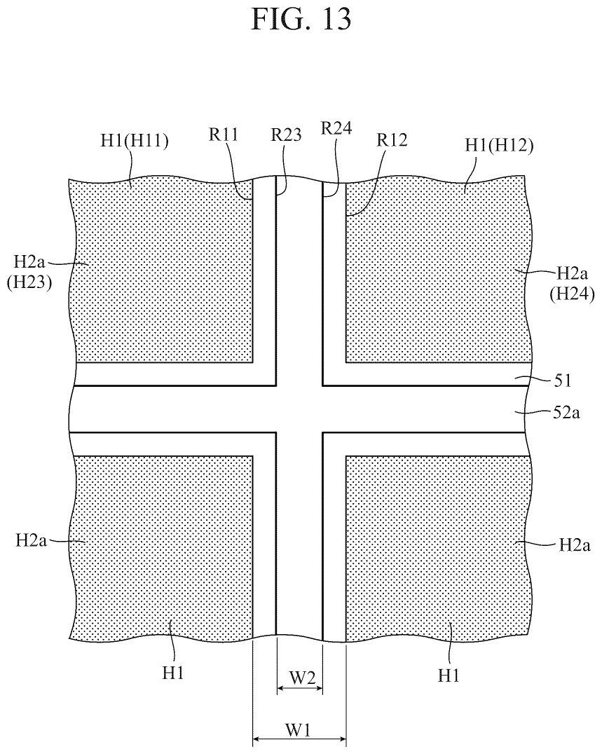

FIG. 13 is an enlarged view of a second blocking unit according to the third embodiment as viewed from the normal direction. Normally, in a case where the first electromagnetic wave blocking mesh and the second electromagnetic wave blocking mesh according to the second embodiment have a plurality of fine openings, even when the plurality of openings of the first electromagnetic wave blocking mesh and the second electromagnetic wave blocking mesh is formed to have the same shape and the same interval, it is difficult to align the first electromagnetic wave blocking mesh and the second electromagnetic wave blocking mesh in a plane direction that is a direction orthogonal to the normal direction so that the edge lines of the openings of the first electromagnetic wave blocking mesh and the openings of the second electromagnetic wave blocking mesh completely overlap when viewed from the normal direction.

For example, in a case where the first electromagnetic wave blocking mesh and the second electromagnetic wave blocking mesh are formed on one surface and the other surface of a single base member 6 by etching or the like as in the second blocking unit 4 according to the first embodiment, it is relatively easy to align the first electromagnetic wave blocking mesh and the second electromagnetic wave blocking mesh in a plane direction, but, in a case where the first electromagnetic wave blocking mesh and the second electromagnetic wave blocking mesh are held by different members, it is difficult to align the first electromagnetic wave blocking mesh and the second electromagnetic wave blocking mesh in a plane direction. The apparent aperture ratio in a case where the first electromagnetic wave blocking mesh and the second electromagnetic wave blocking mesh are viewed from the normal direction is the largest in a state where the edge lines of the openings of the first electromagnetic wave blocking mesh and the openings of the second electromagnetic wave blocking mesh completely overlap when viewed from the normal direction, and, when the edge lines of the openings of the first electromagnetic wave blocking mesh and the openings of the second electromagnetic wave blocking mesh deviate, the visibility of the inside of the housing K1 when viewed from the normal direction drops.

Therefore, the second blocking unit according to the third embodiment includes the first electromagnetic wave blocking mesh 51 formed in a net-like shape having a plurality of openings H1 and a second electromagnetic wave blocking mesh 52a formed in a net-like shape having a plurality of openings H2a, and the openings H2a are formed larger than the openings H1. In other words, the second blocking unit according to the third embodiment includes the first electromagnetic wave blocking mesh 51 formed in a net-like shape having a plurality of openings H1, and the second electromagnetic wave blocking mesh 52a formed in a net-like shape having a plurality of openings H2a so that the aperture ratio thereof is higher than that of the first electromagnetic wave blocking mesh 51.

Further, in other words, the first electromagnetic wave blocking mesh 51 is formed in a net-like shape having a plurality of openings H1 including first openings H11 and second openings H12, and the second electromagnetic wave blocking mesh 52a is formed in a net-like shape having a plurality of openings H2a including third openings H23 and fourth openings H24. The third openings H23 are formed so as to partially overlap the first openings H11 when viewed from the Z direction (see FIG. 3) orthogonal to the second electromagnetic wave blocking mesh 52a, and edge lines R23 of the third openings H23 are positioned so as not to intersect edge lines R11 of the first openings H11 when viewed from the normal direction. The second openings H12 are formed so as to be adjacent to the first openings H11, the fourth openings H24 are formed so as to be adjacent to the third openings H23, the fourth openings H24 are formed so as to overlap the second openings H12 when viewed from the normal direction, and edge lines R24 of the fourth openings H24 are positioned so as not to intersect the edge lines of the second openings H12 when viewed from the normal direction. The first openings H11 and the second openings H12 are formed so that the distance in the plane direction between the first openings H11 and the second openings H12 differs from the distance in the plane direction between the third openings H23 and the fourth openings H24. For example, the first openings H11 and the second openings H12 are formed so that the distance in the plane direction between the first openings H11 and the second openings H12 is greater than the distance in the plane direction between the third openings H23 and the fourth openings H24.

Further, in other words, the second blocking unit according to the third embodiment includes the first electromagnetic wave blocking mesh 51, and the second electromagnetic wave blocking mesh 52a having a plurality of openings H2a that are formed so that the width of wiring lines is smaller than that of the first electromagnetic wave blocking mesh 51. Further, in other words, the second blocking unit according to the third embodiment includes the first electromagnetic wave blocking mesh 51, and the second electromagnetic wave blocking mesh 52a having a plurality of openings H2a that are formed so that the aperture ratio is higher than that of the first electromagnetic wave blocking mesh 51.

For example, the second blocking unit according to the third embodiment includes the first electromagnetic wave blocking mesh 51 formed in a net-like (mesh-like) shape having a plurality of fine openings H1 each having a polygonal shape such as a triangle, a rhombus, a parallelogram, a rectangle, a square, or a hexagon, a circle, an ellipse, or some other shape, and the second electromagnetic wave blocking mesh 52a formed in a net-like shape having a plurality of openings H2a that are formed so as to have the same shape and the same center-to-center distance as those of the openings H1 and to be larger than the openings H1, and the openings H1 of the first electromagnetic wave blocking mesh 51 and the openings H2a of the second electromagnetic wave blocking mesh 52a are formed so that the edge lines thereof do not intersect.

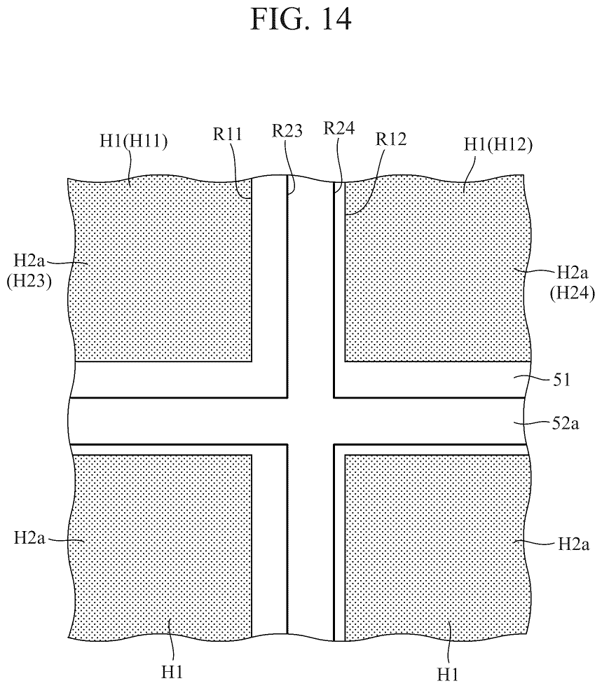

FIG. 14 is an enlarged view of the second blocking unit according to the third embodiment, illustrating a state where the first electromagnetic wave blocking mesh 51 and the second electromagnetic wave blocking mesh 52a are arranged to be shifted in a plane direction as viewed from the normal direction. With the configuration as above, the second blocking unit according to the third embodiment reduces the decrease in the apparent aperture ratio when viewed from the normal direction, and reduces the decrease in the visibility of the inside of the housing K1, even when the first electromagnetic wave blocking mesh 51 and the second electromagnetic wave blocking mesh 52a are arranged to be shifted in a plane direction.

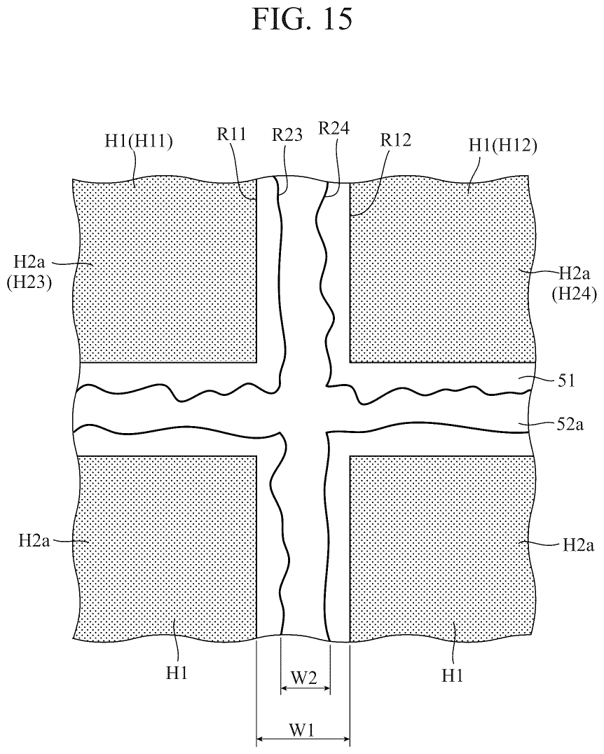

Note that the shapes of the openings H1 and the openings H2a described above might not be as intended due to manufacturing errors or the like. FIG. 15 is an enlarged view of the second blocking unit according to the third embodiment, illustrating a state where there is an error in the shape of the openings H2a of the second electromagnetic wave blocking mesh 52a, as viewed from the normal direction. Even when there is an error in the shape of the openings in such a manner, the second blocking unit according to the third embodiment ensures a sufficiently large difference in size between the openings H1 and the openings H2a. Thus, it is possible to reduce the decrease in the apparent aperture ratio when viewed from the normal direction, and reduce the decrease in visibility of the inside of the housing K1.

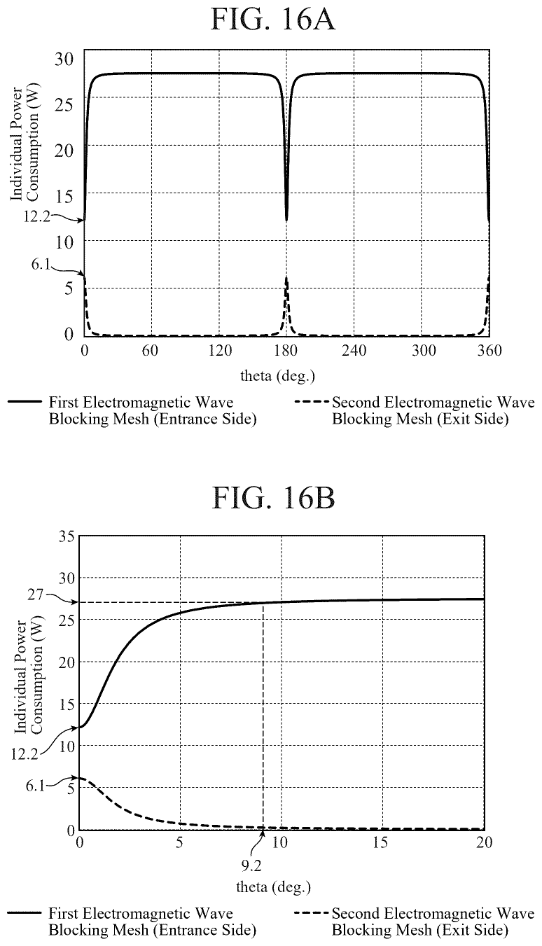

Next, the electric characteristics of the second blocking unit in the electromagnetic wave heating device according to the third embodiment are described with reference to FIG. 16. FIG. 16A is a graph showing the result of a simulation of power consumption by the first electromagnetic wave blocking mesh 51 and the second electromagnetic wave blocking mesh 52a according to the third embodiment, and FIG. 16B is a graph showing part of FIG. 16A in an enlarged manner, showing the result of a simulation of power consumption by the first electromagnetic wave blocking mesh 51 and the second electromagnetic wave blocking mesh 52a according to the third embodiment. Also, FIG. 16B shows the portion from 0° to 20° of the graph in FIG. 16A in an enlarged manner.

In FIGS. 16A and 16B, a solid line indicates power consumption by the first electromagnetic wave blocking mesh 51, and a dashed line indicates power consumption by the second electromagnetic wave blocking mesh 52a. In the simulations according to FIGS. 16A and 16B, the sheet resistance value of the first electromagnetic wave blocking mesh 51 is 4 [Ω/sq.], the sheet resistance value of the second electromagnetic wave blocking mesh 52a is 8 [Ω/sq.], and conditions such as the power of the electromagnetic wave entering the first electromagnetic wave blocking mesh 51 are the same as those in the simulations according to FIGS. 11A and 11B. In other words, the simulations according to FIGS. 16A and 16B are simulations performed in a state where the openings of the second electromagnetic wave blocking mesh 52 are made larger in the simulations according to FIGS. 11A and 11B. As shown in FIGS. 16A and 16B, the power consumption by the first electromagnetic wave blocking mesh 51 is reduced in the vicinities of the electrical distances of 0°, 180°, and 360° between the first electromagnetic wave blocking mesh 51 and the second electromagnetic wave blocking mesh 52a.

Note that, as shown in FIGS. 16A and 16B, in a state where the electrical distance between the first electromagnetic wave blocking mesh 51 and the second electromagnetic wave blocking mesh 52a is 0° or 180°, the power consumption by the first electromagnetic wave blocking mesh 51 is 12.2 [W], the power consumption by the second electromagnetic wave blocking mesh 52a is 6.1 [W], and it can be seen that the power consumption is distributed in proportion to the sheet admittance value that is the reciprocal of the sheet resistance value.

As described above, it is known that the power consumption in a case where only the first electromagnetic wave blocking mesh 51 is irradiated with electromagnetic wave under the same conditions is 27.0 [W], and, in the graphs of the first electromagnetic wave blocking mesh 51 and the second electromagnetic wave blocking mesh 52a shown in FIGS. 16A and 16B, the power consumption by the first electromagnetic wave blocking mesh 51 that consumes more power is 27.0 [W] in cases where the electrical distance between the first electromagnetic wave blocking mesh 51 and the second electromagnetic wave blocking mesh 52a is 9.2°, 170.8°, 189.2°, and 350.8°.

Accordingly, in a case where the electrical distance between the first electromagnetic wave blocking mesh 51 and the second electromagnetic wave blocking mesh 52a is equal to or shorter than 9.2°, is equal to or within 180°±9.2°, or is equal to or within 360°+0/−9.2°, the power consumption by the first electromagnetic wave blocking mesh 51 can be made lower than the power consumption by the first electromagnetic wave blocking mesh 51 in a case where electromagnetic wave is blocked by a single electromagnetic wave blocking mesh having the same sheet resistance value as the first electromagnetic wave blocking mesh 51. In other words, where the distance between the first electromagnetic wave blocking mesh 51 and the second electromagnetic wave blocking mesh 52a is represented by d, and the wavelength of the electromagnetic wave that is generated by the electromagnetic wave generating unit 1 and propagates between the first electromagnetic wave blocking mesh 51 and the second electromagnetic wave blocking mesh 52a is represented by λ, when d is equal to or smaller than λ×9.2°/360°, is equal to or within λ×(180°+9.2°)/360°, or is equal to or within λ×(360°+0/−9.2°)/360°, the first electromagnetic wave blocking mesh 51 can make the power consumption lower than that in a case where electromagnetic wave is blocked by a single electromagnetic wave blocking mesh having the same sheet resistance value as the first electromagnetic wave blocking mesh 51. Further, where N represents a positive integer, d is only required to be equal to or smaller than λ×9.2°/360°, or be equal to or within λ×(180°×N±9.2°)/360° as above.

### Fourth Embodiment

Next, an electromagnetic wave heating device according to a fourth embodiment is described with reference to FIG. 1 and FIGS. 17 and 18. The electromagnetic wave heating device according to the fourth embodiment differs from the electromagnetic wave heating device according to the second embodiment in the shape of the openings of the first electromagnetic wave blocking portion, but the other components are the same, and the same components as those of the second embodiment are denoted by the same reference signs as those used in the second embodiment and are not explained herein.

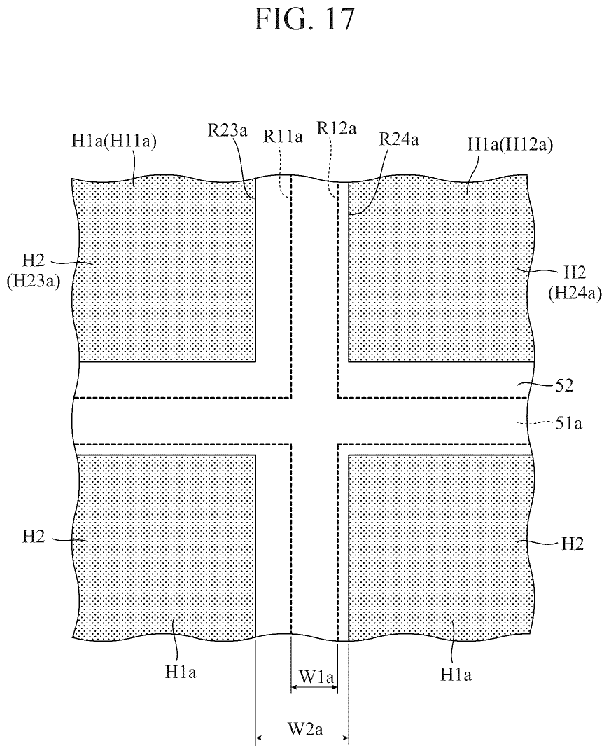

FIG. 17 is an enlarged view of a second blocking unit according to the fourth embodiment as viewed from the normal direction. As shown in FIG. 17, the second blocking unit according to the fourth embodiment includes a first electromagnetic wave blocking mesh 51a formed in a net-like shape having a plurality of openings Hla and a second electromagnetic wave blocking mesh 52 formed in a net-like shape having a plurality of openings H2, and the openings Hla are formed larger than the openings H2. In other words, the second blocking unit according to the fourth embodiment includes the first electromagnetic wave blocking mesh 51a formed in a net-like shape having a plurality of openings Hla, and the second electromagnetic wave blocking mesh 52 formed in a net-like shape having the plurality of openings H2 so that the aperture ratio thereof is smaller than that of the first electromagnetic wave blocking mesh 51a.

Further, in other words, the first electromagnetic wave blocking mesh 51a is formed in a net-like shape having a plurality of openings Hla including first openings H11a and second openings H12a, and the second electromagnetic wave blocking mesh 52 is formed in a net-like shape having a plurality of openings H2 including third openings H23a and fourth openings H24a. The third openings H23a are formed so as to partially overlap the first openings H11a when viewed from the normal direction orthogonal to the second electromagnetic wave blocking mesh 52, and edge lines R23a of the third openings H23a are positioned so as not to intersect edge lines R11a of the first openings H11a when viewed from the normal direction. The second openings H12a are formed so as to be adjacent to the first openings H11a, the fourth openings H24a are formed so as to be adjacent to the third openings H23a, the fourth openings H24a are formed so as to partially overlap the second openings H12a when viewed from the normal direction, and edge lines R24a of the fourth openings H24a are positioned so as not to intersect the edge lines of the second openings H12a when viewed from the normal direction. The first openings H11a and the second openings H12a are formed so that the distance in the plane direction between the first openings H11a and the second openings H12a is shorter than the distance in the plane direction between the third openings H23a and the fourth openings H24a.

Further, in other words, the second blocking unit according to the fourth embodiment includes the first electromagnetic wave blocking mesh 51a, and the second electromagnetic wave blocking mesh 52 having a plurality of openings H2 that are formed so that the width of wiring lines is greater than that of the first electromagnetic wave blocking mesh 51a. Further, in other words, the second blocking unit according to the fourth embodiment includes the first electromagnetic wave blocking mesh 51a, and the second electromagnetic wave blocking mesh 52 having a plurality of openings H2 that are formed so that the aperture ratio is lower than that of the first electromagnetic wave blocking mesh 51a.

For example, the second blocking unit according to the fourth embodiment includes the first electromagnetic wave blocking mesh 51a formed in a net-like (mesh-like) shape having a plurality of fine openings Hla each having a polygonal shape such as a triangle, a rhombus, a parallelogram, a rectangle, a square, or a hexagon, a circle, an ellipse, or some other shape, and the second electromagnetic wave blocking mesh 52 formed in a net-like shape having a plurality of openings H2 that are formed so as to have the same shape and the same center-to-center distance as those of the openings Hla and to be smaller than the openings Hla, and the openings Hla of the first electromagnetic wave blocking mesh 51a and the openings H2 of the second electromagnetic wave blocking mesh 52 are formed so that the edge lines thereof do not intersect.

With such a configuration, in the second blocking unit according to the fourth embodiment, the edge lines of the openings Hla of the first electromagnetic wave blocking mesh 51a are made invisible due to the second electromagnetic wave blocking mesh 52 when viewed from the normal direction, and thus, it is possible to reduce the moire to be caused by both the edge lines of the openings Hla and the edge lines of the openings H2, which are visible. As a result, the second blocking unit according to the fourth embodiment can reduce the decrease in the visibility of the inside of the housing K1 due to the occurrence of moire.

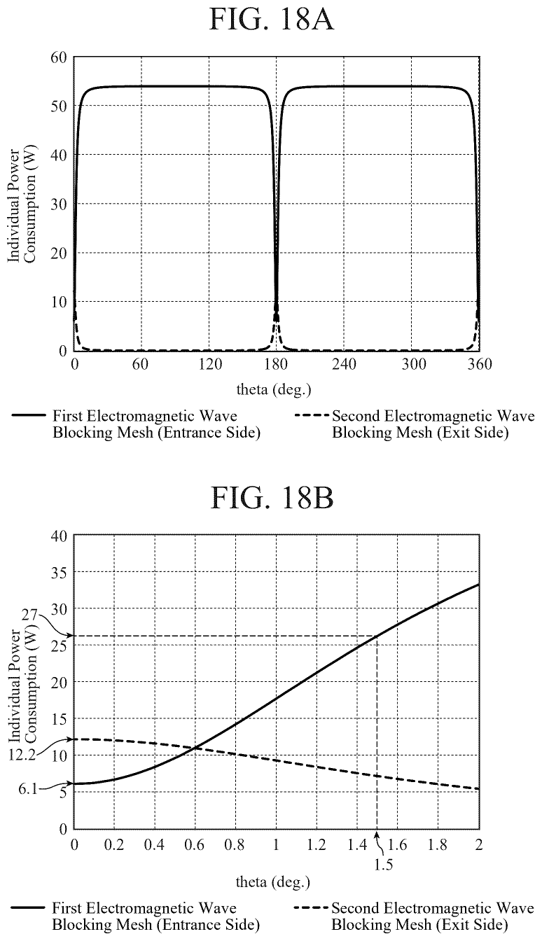

Next, the electric characteristics of the second blocking unit in the electromagnetic wave heating device according to the fourth embodiment are described with reference to FIG. 18. FIG. 18A is a graph showing the result of a simulation of power consumption by the first electromagnetic wave blocking mesh 51a and the second electromagnetic wave blocking mesh 52 according to the fourth embodiment, and FIG. 18B is a graph showing part of FIG. 18A in an enlarged manner, showing the result of a simulation of power consumption by the first electromagnetic wave blocking mesh 51a and the second electromagnetic wave blocking mesh 52 according to the fourth embodiment. Also, FIG. 18B shows the portion from 0° to 2° of the graph in FIG. 18A in an enlarged manner.

In FIGS. 18A and 18B, a solid line indicates power consumption by the first electromagnetic wave blocking mesh 51a, and a dashed line indicates power consumption by the second electromagnetic wave blocking mesh 52. In the simulations according to FIGS. 18A and 18B, the sheet resistance value of the first electromagnetic wave blocking mesh 51a is 8 [Ω/sq.], the sheet resistance value of the second electromagnetic wave blocking mesh 52 is 4 [Ω/sq.], and conditions such as the power of the electromagnetic wave entering the first electromagnetic wave blocking mesh 51a are the same as those in the simulations according to FIGS. 11A and 11B. In other words, the simulations according to FIGS. 18A and 18B are simulations performed in a state where the first electromagnetic wave blocking mesh 51 and the second electromagnetic wave blocking mesh 52a switch positions in the simulations according to FIGS. 16A and 16B. Further, in other words, the simulations according to FIGS. 18A and 18B are simulations performed in a state where the openings of the first electromagnetic wave blocking mesh 51 are made larger in the simulations according to FIGS. 11A and 11B. As shown in FIGS. 18A and 18B, the power consumption by the first electromagnetic wave blocking mesh 51a is reduced in the vicinities of the electrical distances of 0°, 180°, and 360° between the first electromagnetic wave blocking mesh 51a and the second electromagnetic wave blocking mesh 52.

Note that, as shown in FIGS. 18A and 18B, in a state where the electrical distance between the first electromagnetic wave blocking mesh 51a and the second electromagnetic wave blocking mesh 52 is 0° or 180°, the power consumption by the first electromagnetic wave blocking mesh 51a is 6.1 [W], the power consumption by the second electromagnetic wave blocking mesh 52 is 12.2 [W], and it can be seen that the power consumption is distributed in proportion to the sheet admittance value that is the reciprocal of the sheet resistance value.

As described above, it is known that the power consumption in a case where only the first electromagnetic wave blocking mesh 51 according to the second embodiment is irradiated with electromagnetic wave under the same conditions is 27.0 [W], and, in the graphs of the first electromagnetic wave blocking mesh 51a and the second electromagnetic wave blocking mesh 52 shown in FIGS. 18A and 18B, the power consumption by the first electromagnetic wave blocking mesh 51a that is consumes more power is 27.0 [W] in cases where the electrical distance between the first electromagnetic wave blocking mesh 51a and the second electromagnetic wave blocking mesh 52 is 1.5°, 178.5°, 181.5°, and 358.5°.

Accordingly, in a case where the electrical distance between the first electromagnetic wave blocking mesh 51a and the second electromagnetic wave blocking mesh 52 is equal to or shorter than 1.5°, is equal to or within 180°±1.5°, or is equal to or within 360°+0/−1.5°, the power consumption by the first electromagnetic wave blocking mesh 51a can be made lower than the power consumption by the first electromagnetic wave blocking mesh 51a in a case where electromagnetic wave is blocked by a single electromagnetic wave blocking mesh having the same sheet resistance value as that of the first electromagnetic wave blocking mesh 51 according to the second embodiment and that of the second electromagnetic wave blocking mesh 52 according to the fourth embodiment.

In other words, where the distance between the first electromagnetic wave blocking mesh 51a and the second electromagnetic wave blocking mesh 52 is represented by d, and the wavelength of the electromagnetic wave that is generated by the electromagnetic wave generating unit 1 and propagates between the first electromagnetic wave blocking mesh 51a and the second electromagnetic wave blocking mesh 52 is represented by λ, when d is equal to or smaller than λ×1.5°/360°, is equal to or within λ×(180°+1.5°)/360°, or is equal to or within λ×(360°+0/−1.5°)/360°, the first electromagnetic wave blocking mesh 51a can make the power consumption lower than that in a case where electromagnetic wave is blocked by a single electromagnetic wave blocking mesh having the same sheet resistance value as that of the first electromagnetic wave blocking mesh 51a according to the second embodiment. Further, where N represents a positive integer, d is only required to be equal to or smaller than 2×1.5°/360°, or be equal to or within λ×(180°×N±1.5°)/360° as above.

### Fifth Embodiment

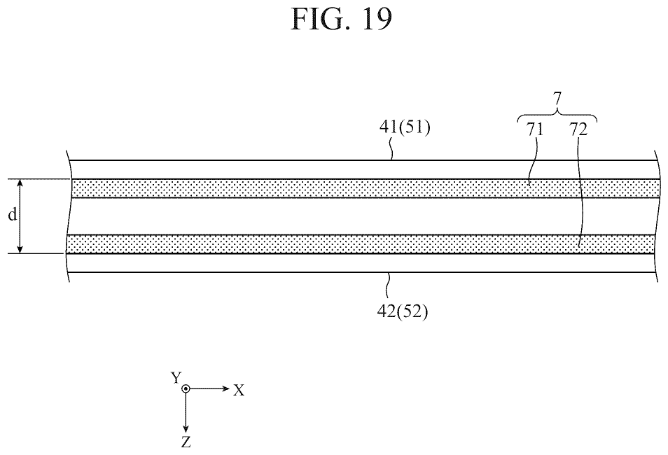

Next, an electromagnetic wave heating device according to a fifth embodiment is described with reference to FIG. 19. The electromagnetic wave heating device according to the fifth embodiment differs from the electromagnetic wave heating device according to the first embodiment in the configuration of the base member, but the other components are the same, and the same components as those of the first embodiment are denoted by the same reference signs as those used in the first embodiment and are not explained herein.

As described above, the base member holding the first electromagnetic wave blocking portion and the second electromagnetic wave blocking portion is not necessarily a single member. For example, the second blocking unit may have a base member formed with a plurality of members formed independently of each other, and the first electromagnetic wave shielding film and the second electromagnetic wave shielding film may be held by different members from each other.

As illustrated in FIG. 19, a second blocking unit according to the fifth embodiment includes a base member 7 held by a first blocking unit 3, a first electromagnetic wave shielding film 41, and a second electromagnetic wave shielding film 42. The base member 7 includes a first member 71 that extends in the X direction and the Y direction and holds the first electromagnetic wave shielding film 41, and a second member 72 that extends in the X direction and the Y direction, is disposed to face the first member 71, and holds the second electromagnetic wave shielding film 42. For example, the first member 71 and the second member 72 are each formed in a plate-like shape or a sheet-like shape with a thickness smaller than the electrical distance d between the first electromagnetic wave shielding film 41 and the second electromagnetic wave shielding film 42.

Note that the first electromagnetic wave blocking portion and the second electromagnetic wave blocking portion held by the first member 71 and the second member 72 may be a first electromagnetic wave blocking mesh and a second electromagnetic wave blocking mesh as described in any of the second to fourth embodiments. For example, the first member 71 and the second member 72 may be formed with polyimide sheets that excel in heat resistance, and may be designed to hold a first electromagnetic wave blocking mesh 51 and a second electromagnetic wave blocking mesh 52 by forming the first electromagnetic wave blocking mesh 51 and the second electromagnetic wave blocking mesh 52 on the surfaces of these polyimide sheets. Also, in such a case, the second blocking unit may be formed with two polyimide sheets that hold the first electromagnetic wave blocking mesh and the second electromagnetic wave blocking mesh, one of the two polyimide sheets being bonded to one surface of a plate-like member formed with glass or the like, the other one of the two polyimide sheets being bonded to the other surface of the plate-like member.

Further, the first electromagnetic wave blocking portion is held by one surface of the first member 71 in the Z direction, and the second electromagnetic wave blocking portion is held by the other surface of the second member 72 in the Z direction. Alternatively, the first electromagnetic wave blocking portion may be held by the other surface of the first member 71 in the Z direction, and the second electromagnetic wave blocking portion may be held by one surface of the second member 72 in the Z direction.

In any of the embodiments described above, the second blocking unit may have both a film-like electromagnetic wave blocking portion and a net-like electromagnetic wave blocking portion. For example, one of the first electromagnetic wave blocking portion and the second electromagnetic wave blocking portion may be formed in a film-like shape, and the other may be formed in a net-like shape. In such a case, power consumption is also distributed to each electromagnetic wave blocking portion in proportion to the sheet admittance value.

Note that, in the present disclosure, it is possible to freely combine each of the embodiments, modify any of the components of each of the embodiments, or omit any of the components in each of the embodiments.

### INDUSTRIAL APPLICABILITY

A conductive housing and an electromagnetic wave heating device according to the present disclosure can be used to heat a heating target housed therein with electromagnetic wave. Also, a sensor device according to the present disclosure can be used for an infrared camera that is hardly affected by electromagnetic wave.

### REFERENCE SIGNS LIST

1: electromagnetic wave generating unit, 2: electromagnetic wave emitting unit, 3: first blocking unit, 4: second blocking unit, 6: base member, 7: base member, 41: first electromagnetic wave shielding film (first electromagnetic wave blocking portion), 42: second electromagnetic wave shielding film (second electromagnetic wave blocking portion), 51: first electromagnetic wave blocking mesh (first electromagnetic wave blocking portion), 51a: first electromagnetic wave blocking mesh (first electromagnetic wave blocking portion), 52: second electromagnetic wave blocking mesh (second electromagnetic wave blocking portion), 52a: second electromagnetic wave blocking mesh (second electromagnetic wave blocking portion), 71: first member, 72: second member, 100: electromagnetic wave heating device, 160: sensor device, 161: first blocking unit, 162: sensor processing device, 163: first electromagnetic wave shielding film, 164: second electromagnetic wave shielding film, 165: second blocking unit, 166: sensor element, H1: opening, H11: first opening, H11a: first opening, H12: second opening, H12a: second opening, Hla: opening, H2: opening, H23: third opening, H23a: third opening, H24: fourth opening, H24a: fourth opening, H2a: opening, K1: housing (conductive housing), N: positive integer, R11: edge line, R11a: edge line, R23: edge line, R23a: edge line, R24: edge line, R24a: edge line, Rs: sheet resistance value, S1: space, d: distance, λ: wavelength

1. An electromagnetic wave heating device comprising:
a conductive housing including:
a first blocker formed with a first conductive material in a box-like shape having an opening portion; and
a second blocker including a first electromagnetic wave blocker that is formed with a second conductive material and extends in a first direction and a second direction orthogonal to the first direction, and a second electromagnetic wave blocker that is formed with a third conductive material, extends in the first direction and the second direction, and is disposed to face the first electromagnetic wave blocker at a distance,
an electromagnetic wave generator to generate electromagnetic wave, the electromagnetic wave generator being disposed in a space formed inside the first blocker and the second blocker; and
an electromagnetic wave emitter to emit the electromagnetic wave generated by the electromagnetic wave generator into the space, wherein
the second blocker is disposed in the opening portion,
the first blocker is electrically connected to the first electromagnetic wave blocker and the second electromagnetic wave blocker, and
a distance between the first electromagnetic wave blocker and the second electromagnetic wave blocker is equal to or within λ×(180°×N±15°)/360°, where λ represents a wavelength of the electromagnetic wave that is generated by the electromagnetic wave generator and propagates between the first electromagnetic wave blocker and the second electromagnetic wave blocker, and N represents an integer equal to or higher than zero.

2. An electromagnetic wave heating device comprising:
a conductive housing including:
a first blocker formed with a first conductive material in a box-like shape having an opening portion;
and a second blocker including a first electromagnetic wave blocker that is formed with a second conductive material and extends in a first direction and a second direction orthogonal to the first direction, and a second electromagnetic wave blocker that is formed with a third conductive material, extends in the first direction and the second direction, and is disposed to face the first electromagnetic wave blocker at a distance;
an electromagnetic wave generator to generate electromagnetic wave, the electromagnetic wave generator being disposed in a space formed inside the first blocker and the second blocker; and
an electromagnetic wave emitter to emit the electromagnetic wave generated by the electromagnetic wave generator into the space, wherein
the second blocker is disposed in the opening portion,
the first blocker is electrically connected to the first electromagnetic wave blocker and the second electromagnetic wave blocker, and
a distance between the first electromagnetic wave blocker and the second electromagnetic wave blocker is equal to or within λ×(180°×N±12°)/360°, where λ represents a wavelength of the electromagnetic wave that is generated by the electromagnetic wave generator and propagates between the first electromagnetic wave blocker and the second electromagnetic wave blocker, and N represents an integer equal to or higher than zero.

3. An electromagnetic wave heating device comprising:
a conductive housing including:
a first blocker formed with a first conductive material in a box-like shape having an opening portion;
and a second blocker including a first electromagnetic wave blocker that is formed with a second conductive material and extends in a first direction and a second direction orthogonal to the first direction, and a second electromagnetic wave blocker that is formed with a third conductive material, extends in the first direction and the second direction, and is disposed to face the first electromagnetic wave blocker at a distance;
an electromagnetic wave generator to generate electromagnetic wave, the electromagnetic wave generator being disposed in a space formed inside the first blocker and the second blocker; and
an electromagnetic wave emitter to emit the electromagnetic wave generated by the electromagnetic wave generator into the space, wherein
the second blocker is disposed in the opening portion,
the first blocker is electrically connected to the first electromagnetic wave blocker and the second electromagnetic wave blocker, and
a distance between the first electromagnetic wave blocker and the second electromagnetic wave blocker is equal to or within λ×(180°×N±7.5°)/360°, where λ represents a wavelength of the electromagnetic wave that is generated by the electromagnetic wave generator and propagates between the first electromagnetic wave blocker and the second electromagnetic wave blocker, and N represents an integer equal to or higher than zero.

4. An electromagnetic wave heating device comprising:
a conductive housing including:
a first blocker formed with a first conductive material in a box-like shape having an opening portion;
and a second blocker including a first electromagnetic wave blocker that is formed with a second conductive material and extends in a first direction and a second direction orthogonal to the first direction, and a second electromagnetic wave blocker that is formed with a third conductive material, extends in the first direction and the second direction, and is disposed to face the first electromagnetic wave blocker at a distance;
an electromagnetic wave generator to generate electromagnetic wave, the electromagnetic wave generator being disposed in a space formed inside the first blocker and the second blocker; and
an electromagnetic wave emitter to emit the electromagnetic wave generated by the electromagnetic wave generator into the space, wherein
the second blocker is disposed in the opening portion,
the first blocker is electrically connected to the first electromagnetic wave blocker and the second electromagnetic wave blocker, and
a distance between the first electromagnetic wave blocker and the second electromagnetic wave blocker is equal to or within λ×(180°×N±6°)/360°, where λ represents a wavelength of the electromagnetic wave that is generated by the electromagnetic wave generator and propagates between the first electromagnetic wave blocker and the second electromagnetic wave blocker, and N represents an integer equal to or higher than zero.

5. The electromagnetic wave heating device according to claim 1, wherein
the first electromagnetic wave blocking portion is formed in a net-like shape having a plurality of openings including a first opening and a second opening, and
the second electromagnetic wave blocking portion is formed in a net shape having a plurality of openings including a third opening and a fourth opening.

6. The electromagnetic wave heating device according to claim 5, wherein
the third opening is formed so as to overlap the first opening when viewed from a direction orthogonal to the second electromagnetic wave blocking portion, and
an edge line of the third opening is positioned so as not to intersect an edge line of the first opening when viewed from the direction orthogonal to the second electromagnetic wave blocking portion.

7. The electromagnetic wave heating device according to claim 6, wherein
the second opening is formed so as to be adjacent to the first opening,
the fourth opening is formed so as to be adjacent to the third opening, and is formed so as to overlap the second opening when viewed from the direction orthogonal to the second electromagnetic wave blocking portion, and
an edge line of the fourth opening is positioned so as not to intersect an edge line of the second opening when viewed from the direction orthogonal to the second electromagnetic wave blocking portion.

8. The electromagnetic wave heating device according to claim 7, wherein
the first opening and the second opening are formed so that a distance in a plane direction between the first opening and the second opening differs from a distance in a plane direction between the third opening and the fourth opening.

9. The electromagnetic wave heating device according to claim 7, wherein
the first electromagnetic wave blocking portion is disposed at a position closer to the space than the second electromagnetic wave blocking portion, and
the first opening and the second opening are formed so that a distance in a plane direction between the first opening and the second opening is shorter than a distance in a plane direction between the third opening and the fourth opening.

10. The electromagnetic wave heating device according to claim 7, wherein
the first electromagnetic wave blocking portion and the second electromagnetic wave blocking portion are formed with a material that transmits part of visible light.

11. The electromagnetic wave heating device according to claim 7, wherein
the second blocker includes a base member to hold the first electromagnetic wave blocking portion and the second electromagnetic wave blocking portion, the base member being formed with a non-conductive material.

12. The electromagnetic wave heating device according to claim 11, wherein
the base member is formed in a plate-like shape extending in the first direction and the second direction, one surface of the base member holds the first electromagnetic wave blocking portion, and another surface of the base member holds the second electromagnetic wave blocking portion.

13. The electromagnetic wave heating device according to claim 11, wherein
the base member includes: a first member to hold the first electromagnetic wave blocking portion, the first member extending in the first direction and the second direction; and a second member to hold the second electromagnetic wave blocking portion, the second member extending in the first direction and the second direction, and being disposed to face the first member.

14. The electromagnetic wave heating device according to claim 11, wherein
the base member is formed with a material that transmits part of visible light.

15. The electromagnetic wave heating device according to claim 11, wherein
the base member is inorganic glass or heat-resistant polyimide.

16. The electromagnetic wave heating device according to claim 1, wherein
the first blocker and the second blocker connect the space to outside the space, and are formed so as not to have a gap larger than 1/10 of a wavelength of the electromagnetic wave emitted from the electromagnetic wave emitter.
